(19) United States
(12) Patent Application Publication
(10) Pub. No.: US 2025/0116031 A1
(43) Pub. Date: Apr. 10, 2025

(54) SCINTILLATION CRYSTAL AND PREPARATION METHOD AND PREPARATION DEVICE THEREOF

(71) Applicant: MEISHAN BOYA ADVANCED MATERIALS CO., LTD., Meishan (CN)

(72) Inventors: Yu WANG, Meishan (CN); Weiming GUAN, Meishan (CN)

(73) Assignee: MEISHAN BOYA ADVANCED MATERIALS CO., LTD., Meishan (CN)

(21) Appl. No.: 18/903,326

(22) Filed: Oct. 1, 2024

(30) Foreign Application Priority Data
Oct. 7, 2023 (CN) 202311301252.3

(51) Int. Cl. C30B 29/22; C01B 33/20; C09K 11/77; C30B 27/02; C30B 29/12

(52) U.S. Cl. CPC C30B 29/22; C01B 33/20; C09K 11/77742; C30B 27/02; C30B 29/12; C01P 2002/52

(57) ABSTRACT

One embodiment of the present disclosure provides a scintillation crystal and a method and a device for preparing the scintillation crystal. A molecular formula of the scintillation crystal is: Ce_{y}:Caₛ:Lu_{2(1-xysz)}Y_{2z}Sc₂ₓSiO₅, wherein x=0-1, y=0.0000001-0.06, z=0.00001-0.5, s=0.0000001-0.05.

### CROSS-REFERENCE TO RELATED APPLICATIONS

This application claims priority of Chinese Patent Application No. 202311301252.3 filed Oct. 7, 2023, the entire contents of which are incorporated herein by reference.

### TECHNICAL FIELD

The present disclosure relates to the field of artificial crystal growth, and in particular to a scintillation crystal and a preparation method and a preparation device thereof.

### BACKGROUND

As one of the optimal scintillation crystals in terms of comprehensive performance at present, cerium (Ce)-doped lutetium silicate (Lu) is a high-density and high-atomic-order scintillation crystal that has the unique advantages of fast response time to gamma rays, high light yield, certain energy resolution, no deliquescence, and low sensitivity to neutrons. When a large-sized scintillation crystal is prepared, the size, scintillation performance, and mechanical properties of the scintillation crystal may be affected due to deviations in doping concentration of Ce or the volatilization of silicon dioxide (SiO₂) at high temperature.

Therefore, it is desirable to provide a scintillation crystal and a preparation method and a preparation device thereof, such that the prepared scintillation crystal has good growth repeatability, stable comprehensive performance, and few macroscopic defects.

### SUMMARY

One of the embodiments of the present disclosure provides a scintillation crystal. A molecular formula of the scintillation crystal may be expressed as:

$$L {u}_{2 ( 1 - x - m - z )} {X}_{2 x} {M}_{2 m} {y}_{2 z} {SiQ}_{( 5 - \frac{n}{2} )} {N}_{n} ,$$

wherein X is composed of Ce, M is composed of one or more of Ca, Mg, Sr, Mn, Ba, Al, Fe, Re, La, Pr, Nd, Pm, Sm, Eu, Gd, Tb, Dy, Ho, Er, Yb, Tm, Lu, and Sc, Q is composed of O, N is composed of Cl and one or more of F, Br, and S; wherein x=0.0000001-0.06, m=0-0.06, 0≤z<1, 0<n<10.

One of the embodiments of the present disclosure provides a method for preparing a scintillation crystal. The method may be configured to prepare the scintillation crystal described in the embodiments of the present disclosure. A reaction equation for preparing the scintillation crystal may be:

$$( 1 - x - y - s - z ) {Lu}_{2} {O}_{3} + {zY}_{2} {O}_{3} + {ySc}_{2} {O}_{3} + \frac{n}{2} {CeCl}_{3} + ( 2 x - \frac{n}{2} ) {CeO}_{2} + 2 sCa 0 + {SiO}_{2} = {Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} + \frac{( x - s - \frac{n}{2} )}{2} {O}_{2} ,$$

wherein, x=0.0000001-0.06, 0<s<0.05, 0≤y<1, 0≤z<1, 0<n<10. The method may comprise: weighing reaction materials according to a molar ratio based on the reaction equation; and preparing the scintillation crystal using the weighed reaction materials.

One of the embodiments of the present disclosure provides a device for preparing a scintillation crystal. The device may be configured to prepare the scintillation crystals described in the embodiments of the present disclosure. The device for preparing the scintillation crystal may comprise a furnace, a temperature field device, a lifting rod, a first heating device, a first driving device, and a crucible. The temperature field device and the first heating device may be disposed in the furnace. The crucible may be disposed in the temperature field device and configured to accommodate reaction materials for preparing the scintillation crystal. At least a portion of the lifting rod may be disposed in the furnace. The first driving device may be connected with the lifting rod to drive the lifting rod to move along an axial direction of the lifting rod.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a schematic diagram illustrating an exemplary scintillation crystal according to some embodiments of the present disclosure;

FIG. 2A is a schematic diagram illustrating an exemplary device for preparing a scintillation crystal according to some embodiments of the present disclosure;

FIG. 2B is a schematic structural diagram illustrating an exemplary vacuum furnace according to some embodiments of the present disclosure;

FIG. 2C is a schematic structural diagram illustrating an exemplary open furnace according to some embodiments of the present disclosure;

FIG. 2D is a schematic diagram illustrating an exemplary temperature field device of an open furnace according to some embodiments of the present disclosure;

FIG. 3 is a flowchart illustrating an exemplary method for preparing a scintillation crystal according to some embodiments of the present disclosure;

FIG. 4 is a schematic diagram illustrating an exemplary fully oxidized scintillation crystal according to some embodiments of the present disclosure;

FIG. 5 is a schematic diagram illustrating another exemplary scintillation crystal according to some embodiments of the present disclosure;

FIG. 6 is a schematic diagram illustrating another exemplary scintillation crystal according to some embodiments of the present disclosure;

FIG. 7 is a schematic diagram illustrating another exemplary scintillation crystal according to some embodiments of the present disclosure;

FIG. 8 is a schematic diagram illustrating another exemplary scintillation crystal according to some embodiments of the present disclosure;

FIG. 9 is a schematic diagram illustrating an exemplary relative position of a crucible and a filler according to some embodiments of the present disclosure;

FIG. 10 is a schematic diagram illustrating an exemplary first portion of a crucible wall according to some embodiments of the present disclosure;

FIG. 11 is a schematic diagram illustrating an exemplary second portion of a crucible wall according to some embodiments of the present disclosure;

FIG. 12 is a schematic diagram illustrating an exemplary target region of a bottom of a crucible according to some embodiments of the present disclosure; and

FIG. 13 is a schematic diagram illustrating exemplary convection loops according to some embodiments of the present disclosure.

Reference signs: 200, device for preparing a scintillation crystal; 201, vacuum furnace; 202, open furnace; 210, furnace chamber; 220, temperature field device; 221, crucible; 230, lifting rod; 240, first heating device; 250, first driving device; 260, second driving device; 251, lifting assembly; 252, rotating assembly; 253, weighing device; 226, first bottom plate; 229, furnace frame; 2210, movement device; 222, bottom plate; 223, first cylinder; 224, second cylinder; 225, filler; 227, second cover plate; 228, second heating device; 2213, induction coil.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system”, “device”, “unit” and/or “module” used herein are a way to distinguish between different components, elements, parts, sections, or assemblies at different levels. However, the terms may be replaced by other expressions if other words accomplish the same purpose.

As shown in the present disclosure and in the claims, unless the context clearly suggests an exception, the words “one”, “a”, “an”, “one kind”, and/or “the” do not refer specifically to the singular, but may also include the plural. Generally, the terms “including” and “comprising” suggest only the inclusion of clearly identified steps and elements, however, the steps and elements that do not constitute an exclusive list, and the method or apparatus may also include other steps or elements.

Flowcharts are used in the present disclosure to illustrate the operations performed by a system according to embodiments of the present disclosure, and the related descriptions are provided to aid in a better understanding of the magnetic resonance imaging method and/or system. It should be appreciated that the preceding or following operations are not necessarily performed in an exact sequence. Instead, steps can be processed in reverse order or simultaneously. Also, it is possible to add other operations to these processes or to remove a step or steps from these processes.

Scintillation crystals are widely used in nuclear medicine such as X-ray tomography (XCT), and positron emission tomography (PET), nuclear detection technology such as industrial tomography (industrial CT), oil well exploration, nuclear physics, high energy physics, environmental testing, safety testing, weaponry fire control, guidance, and other fields. Especially in the field of high energy physics and nuclear medicine imaging, scintillation crystals are required to have high light yield, high absorption of gamma rays, short luminescence decay time, large irradiation hardness, density, atomic order, etc.

As one of the optimal scintillation crystals in terms of comprehensive performance at present, cerium (Ce)-doped lutetium silicate (LSO) is a high-density, high-atomic-order scintillation crystal that has the unique advantages of fast response time to gamma rays, high light yield, certain energy resolution, no deliquescence, and low sensitivity to neutrons.

By doping with divalent cations, especially Ca²⁺ and Mg²⁺, the scintillation properties of cerium-doped scintillation crystals can be improved to a certain extent. However, the growth of the scintillation crystals is not stable. A relatively high Ca concentration may lead to an increased viscosity of a melt, reduced surface tension and reduced heat transfer, affecting the stability of crystal growth.

However, how to control the total content of a second dopant (e.g., a compound including the divalent cations Ca²⁺, Mg²⁺, etc.) in the scintillation crystal and adjust the content of Ce⁴⁺ and/or Ce³⁺ in the crystal have become urgent issues to improve the performance of the scintillation crystals.

It is found in the production practice that even if the purity of each batch of raw materials meets the standard requirements, the content of various impurity elements (e.g., Cl, Ca, etc.) may be different, which may have an adverse effect on the production.

Some existing technologies avoid the adverse effect by limiting the content of some impurity elements in the raw materials. The content of Ce⁴⁺ and/or Ce³⁺ in the scintillation crystal is adjusted by reheating the crystal to a certain temperature after the crystal growth is completed, then diffusing oxygen and adding the divalent cations. These processes may significantly increase the production cost.

According to the present disclosure, by introducing anions such as Cl⁻, the total content of group II elements such as Ca and Mg is reduced, the content of Ce⁴⁺ and/or Ce³⁺ in L(Y)SO crystals is adjusted, and the effect of fluctuations in the content of different impurity elements in different batches on the crystal growth and the crystal performance is avoided without significantly increasing the production cost. The introduced Cl⁻ can supplement some oxygen vacancies in the scintillation crystal, adjust the content of Ce⁴⁺ and/or Ce³⁺ in the scintillation crystal, and work together with the divalent cations such as Ca and Mg to reduce afterglow, effectively improving the scintillation performance of the scintillation crystal. Cl⁻ may be introduced through compounds including Cl⁻ such as CeCl₃ or CeCl₄.

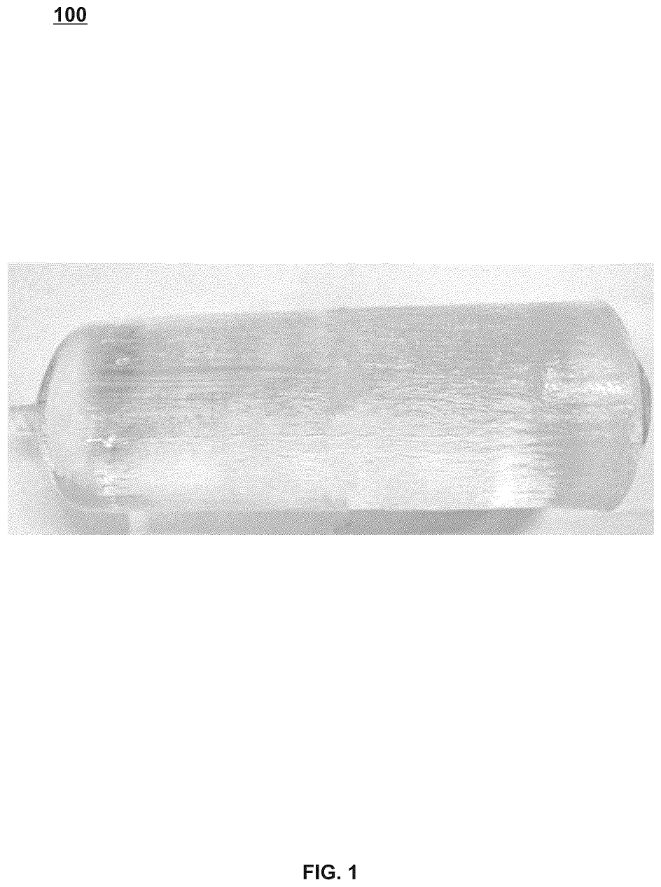

FIG. 1 is a schematic diagram illustrating an exemplary scintillation crystal according to some embodiments of the present disclosure.

The present disclosure provides a scintillation crystal. A molecular formula of the scintillation crystal may be expressed as:

$${Lu}_{2 ( 1 - x - m - z )} {X}_{2 x} {M}_{2 m} {Y}_{2 z} {SiQ}_{( 5 - \frac{n}{2} )} {N}_{n} ,$$

wherein X is composed of Ce, M is composed of one or more of Ca, Mg, Sr, Mn, Ba, Al, Fe, Re, La, Pr, Nd, Pm, Sm, Eu, Gd, Tb, Dy, Ho, Er, Yb, Tm, Lu, and Sc, Q is composed of O, N is composed of CI and one or more of F, Br, and S.

The scintillation crystal refers to a crystal capable of converting the kinetic energy of high-energy particles such as X-rays into light energy and emit flashes of light when impacted by the high-energy particles.

In the molecular formula, 2x represents a doping concentration of X, 2m represents a doping concentration of M, 2z represents a doping concentration of trivalent yttrium ions (Y³⁺), and n represents an atomic concentration of N.

In some embodiments, a value of x may be within a range of 0.0000001-0.06 (this representation includes boundary values 0.0000001 and 0.06). The value of x may be within a range of 0.00001-0.06. The value of x may be within a range of 0.0001-0.06. The value of x may be within a range of 0.001-0.06. The value of x may be within a range of 0.01-0.06. The value of x may be within a range of 0.02-0.05. The value of x may be within a range of 0.03-0.04. The value of x may be within a range of 0.031-0.039. The value of x may be within a range of 0.032-0.038. The value of x may be within a range of 0.033-0.037. The value of x may be within a range of 0.034-0.036. In some embodiments, a value of m may be within a range of 0-0.06. The value of m may be within a range of 0.001-0.06. The value of m may be within a range of 0.002-0.05. The value of m may be within a range of 0.003-0.04. The value of m may be within a range of 0.0031-0.0039. The value of m may also be 0.0032-0.0038. The value of m may also be 0.0033-0.0037. The value of m may be within a range of 0.0034-0.0036. In some embodiments, a value of z may be 0≤z<1. The value of z may be within a range of 0.1-0.9. The value of z may be within a range of 0.2-0.8. The value of z may be within a range of 0.3-0.7. The value of z may be within a range of 0.4-0.6. The value of z may be within a range of 0.42-0.58. The value of z may be within a range of 0.44-0.56. The value of z may be within a range of 0.46-0.54. The value of z may be within a range of 0.48-0.52. The value of z may be within a range of 0.49-0.51. In some embodiments, a value of n may be 0<n<10. The value of n may be within a range of 0.5-4.5. The value of n may be within a range of 1-4. The value of n may be within a range of 1.5-3.5. The value of n may be within a range of 2-3. The value of n may be within a range of 2.2-2.8. The value of n may be within a range of 2.4-2.6.

In some embodiments, X may be composed of Ce, M may be composed of Ca or M may be composed of Ca and Sc, Q may be composed of O, N may be composed of Cl. The molecular formula of the scintillation crystal may be expressed as:

$${Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} .$$

In the present disclosure, the scintillation crystal corresponding to the molecular formula may be referred to as Ce:Ca:LYSSOC.

It can be understood that 2x represents a doping concentration of trivalent cerium ions (Ce³⁺) and tetravalent cerium ions (Ce⁴⁺), i.e., a proportion of Ce³⁺ in a lutetium (Lu) atomic lattice site, 2s represents a proportion of divalent calcium ions (Ca²⁺) in a scintillation crystal lattice site, 2y represents a doping concentration of trivalent scandium ions (Sc³⁺), 2z represents an atomic concentration of trivalent yttrium ions (Y³⁺), and n represents an atomic concentration of chloride ions (Cl⁻).

The values of x, z, and n may be found in the related descriptions above, which are not repeated here. In some embodiments, a value of s may be 0<s<0.05. The value of s may be within a range of 0.01-0.04. The value of s may be within a range of 0.02-0.03. The value of s may be within a range of 0.021-0.029. The value of s may be within a range of 0.022-0.028. The value of s may be 0.001, 0.005, 0.01, 0.015, 0.02, 0.025, 0.03, 0.035, 0.04, 0.045, etc. A value of y may be 0≤y<1. The value of y may be within a range of 0.1-0.9. The value of y may be within a range of 0.3-0.7. The value of y may be within a range of 0.4-0.6. The value of y may be within a range of 0.51-0.59. The value of y may be 0.045, 0.04, 0.035, 0.03, 0.025, 0.02, 0.015, 0.01, 0.005, 0.001, etc. In some embodiments, a sum of the value of s and the value of y may be equal to the value of m.

By further limiting y and s within the above range, the scintillation performance of the scintillation crystal can be improved (e.g., reducing the afterglow of the scintillation crystal, increasing the light output, etc.). The content of Ce⁴⁺ and/or Ce³⁺ in the scintillation crystal can be adjusted by adjusting y, s, and n.

In some embodiments, a ratio of a mass of CI to a sum of masses of Lu, Ce, Sc, and Y in the scintillation crystal may be within a range of 0.01 ppm-1000 ppm. The ratio of the mass of CI to the sum of the masses of Lu, Ce, Sc, and Y in the scintillation crystal may be within a range of 0.1 ppm-90 0 ppm. The ratio of the mass of CI to the sum of the masses of Lu, Ce, Sc and Y in the scintillation crystal may be within a range of 0.1 ppm-800 ppm. The ratio of the mass of Cl to the sum of the masses of Lu, Ce, Sc, and Y in the scintillation crystal may be within a range of 0.1 ppm-700 ppm. The ratio of the mass of Cl to the sum of the masses of Lu, Ce, Sc, and Y in the scintillation crystal may be within a range of 0.1 ppm-500 ppm. The ratio of the mass of Cl to the sum of the masses of Lu, Ce, Sc, and Y in the scintillation crystal may be within a range of 0.1 ppm-200 ppm. The ratio of the mass of Cl to the sum of the masses of Lu, Ce, Sc and Y in the scintillation crystal may be within a range of 100 ppm-150 ppm.

In some embodiments of the present disclosure, by making the scintillation crystal include Cl, some oxygen vacancies in the scintillation crystal can be supplemented; by setting the ratio of the mass of Cl to the sum of the masses of Lu, Ce, Sc, and Y in the scintillation crystal to be within a range of 0.01 ppm-1000 ppm, the content of Ce⁴⁺ and/or Ce³⁺ in the scintillation crystal can be adjusted, thereby reducing afterglow of the scintillation crystal and improving the light yield.

By doping the scintillation crystal with Ce, Y, Sc (scandium, Sc⁺³ has a radius of 0.0745 nm), and Ca (calcium), the size of the obtained scintillation crystal can be larger. In some embodiments, a diameter of the scintillation crystal can be within a range of 70 mm-115 mm, and a weight of the scintillation crystal can be within a range of 6500 g-13000 g. In addition, the growth repeatability and the performance consistency of the scintillation crystal are good, and the testing proves that the scintillation crystal has few macroscopic defects.

In some embodiments of the present disclosure, by setting the molecular formula of the scintillation crystal and the concentration ratio of each element, the component deviation of the scintillation crystal can be avoided, the doping concentration of Ce under different process conditions can be ensured to be consistent, the repeatability of crystal growth is excellent, and the crystal has good comprehensive performance, and has important application potential in the fields of nuclear medicine, industrial CT, security inspection, environmental monitoring, etc. The testing proves that the diameter of the scintillation crystal provided in the present disclosure can be within a range of 70 mm-115 mm, and an equal diameter length can be within a range of 130 mm-200 mm. The equal diameter length refers to a diameter length achieved in an equal diameter process through an up-pulling method (a Czochralski process). The crystal density can be within a range of 7-7.4 g/cm³. A luminous center wavelength of the crystal can be within a range of 350-450 nm. The light output can reach 23000 ph/MeV and above. An energy resolution can be ≤9%. The minimum decay time can reach 35 nS and below. The crystal has excellent comprehensive performance.

In some embodiments, the elements in the scintillation crystal have different mass ratios.

In some embodiments, a mass ratio of Ca to Ce in the scintillation crystal may not be greater than 300. The mass ratio of Ca to Ce in the scintillation crystal may be within a range of 0.001-250. The mass ratio of Ca to Ce in the scintillation crystal may be within a range of 0.001-200. The mass ratio of Ca to Ce in the scintillation crystal may be within a range of 0.001-150. The mass ratio of Ca to Ce in the scintillation crystal may be within a range of 0.001-100. The mass ratio of Ca to Ce in the scintillation crystal may be within a range of 0.001-50. The mass ratio of Ca to Ce in the scintillation crystal may be within a range of 0.001-20.

In some embodiments of the present disclosure, by limiting the mass ratio of Ca to Ce in the scintillation crystal, the effect of improving the crystal decay time and increasing the light yield (greater than 28000 ph/MeV) can be achieved.

In some embodiments, the scintillation crystal may include at least 1 ppm of Ce³⁺ and/or Ce⁴⁺.

By limiting the content of Ce³⁺ and/or Ce⁴⁺ in the scintillation crystal, the effect of improving afterglow and reducing the decay time of the scintillation crystal can be achieved.

In some embodiments, a first dopant and a second dopant may be added when the scintillation crystal is prepared.

The first dopant refers to a compound including Ce, such as, CeO₂, Ce₂O₃, CeCl₃, CeCl₄, etc. In some embodiments, a mass ratio of Ce to a rare earth element in the first dopant may be at least 10 ppm. The mass ratio of Ce to the rare earth element in the first dopant may be within a range of 10-500 ppm. The mass ratio of Ce to the rare earth element in the first dopant may be within a range of 100-400 ppm. The mass ratio of Ce to the rare earth element in the first dopant may be within a range of 200-300 ppm.

In some embodiments, the second dopant may include M. More descriptions regarding M may be found in the related descriptions above. In some embodiments, the second dopant may include Ca or Sc. For example, the second dopant may be Sc₂O₃ or CaO, etc. In some embodiments, a mass ratio of M to a rare earth element in the second dopant may be within a range of 0.1 ppm-500 ppm. The mass ratio of M to the rare earth element in the second dopant may be within a range of 1 ppm-499 ppm. The mass ratio of M to the rare earth element in the second dopant may be within a range of 100 ppm-400 ppm. The mass ratio of M to the rare earth element in the second dopant may be within a range of 250 ppm-350 ppm. The mass ratio of M to the rare earth element in the second dopant may be within a range of 301 ppm-309 ppm.

It can be understood that rare earth element refers to Y, Sc and lanthanide elements (La to Lu) in the periodic table. Merely by way of example, if the molecular formula of the scintillation crystal is

$${Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} ,$$

the mass ratio of Ce to all rare earth elements (Lu, Y, Sc, and Ce) in the scintillation crystal may be at least 10 ppm. If the molecular formula of the scintillation crystal is

$${Lu}_{2 ( 1 - x - s - z )} {Ce}_{2 x} {Ca}_{2 s} {Y}_{2 z} {SiO}_{( 5 - \frac{n}{2} )} {Cl}_{n} ,$$

the mass ratio of Ce to all rare earth elements (Lu, Y, and Ce) in the scintillation crystal may be at least 10 ppm. If the molecular formula of the scintillation crystal is

$${Lu}_{2 ( 1 - x - s )} {Ce}_{2 x} {Ca}_{2 s} {SiO}_{( 5 - \frac{n}{2} )} {Cl}_{n} ,$$

the mass ratio of Ce to all rare earth elements (Lu and Ce) in the scintillation crystal may be at least 10 ppm.

In some embodiments, a mass ratio of M in the second dopant to Ce in the first dopant may be within a range of 0.01-50. The mass ratio of M in the second dopant to Ce in the first dopant may be within a range of 0.1-40. The mass ratio of M in the second dopant to Ce in the first dopant may be within a range of 1-30. The mass ratio of M in the second dopant to Ce in the first dopant may be within a range of 15-20.

In some embodiments of the present disclosure, by limiting the type of the first dopant and the mass ratio of Ce to the rare earth element in the first dopant, the effect of increasing the light yield of the crystal can be achieved. By limiting the type of the second dopant and the mass ratio of M to the rare earth element in the second dopant, and the mass ratio of M in the second dopant to Ce in the first dopant, the crystal embryo with no spiral or with very low spiral can be prepared, achieving good (short) decay time and scintillation performance.

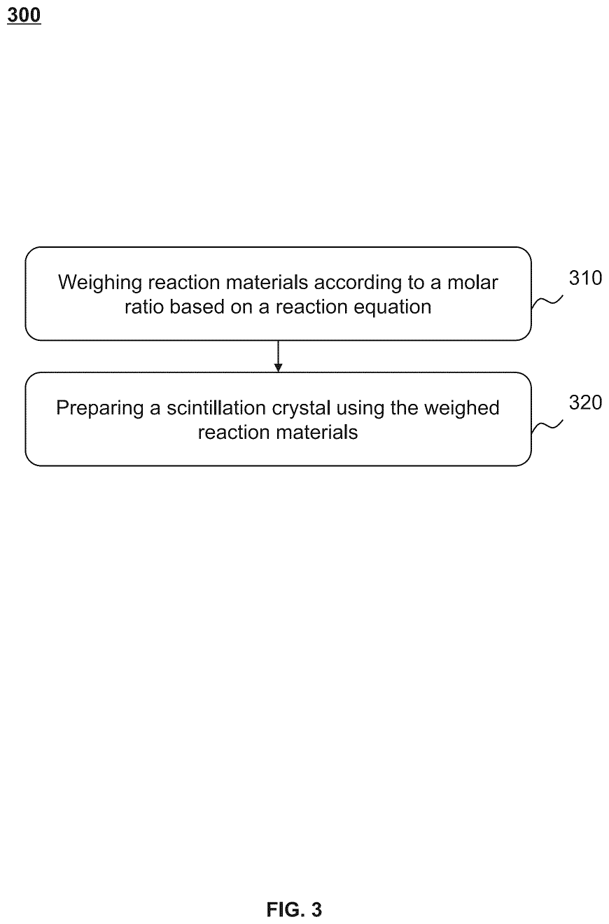

In some embodiments, the reaction equation for preparing the scintillation crystal may be expressed as:

$$( 1 - x - m - z ) {Lu}_{2} {O}_{3} + {zY}_{2} {O}_{3} + {ySc}_{2} {O}_{3} + {ySc}_{2} {O}_{3} + \frac{n}{3} {CeCl}_{3} + ( 2 x - \frac{n}{2} ) {CeO}_{2} + 2 sCaO + {SiO}_{2} = {Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} + \frac{( x - s - \frac{n}{2} )}{2} {O}_{2} ,$$

wherein x=0.0000001-0.06, 0<s<0.05, 0≤y<1, 0≤z<1, 0<n<10. The method for preparing the scintillation crystal may include: preparing the scintillation crystal using an up-pulling method based on the reaction equation. More descriptions regarding the method for preparing the scintillation crystal may be found in FIG. 3 and related descriptions thereof.

By setting the molecular formula of the scintillation crystal and the concentration ratio of each element, the component deviation of the scintillation crystal can be avoided, the Ce doping concentration under different process conditions can be ensured to be consistent, the crystal growth repeatability is excellent, and the crystal has good comprehensive performance, and has important application potential in the fields of nuclear medicine, industrial CT, security inspection, environmental monitoring, etc. The testing proves that the diameter of the Ce:Ca:LYSSO crystal provided in the present disclosure can be within a range of 70 mm-115 mm, and the equal diameter length can be within a range of 130 mm-200 mm. The equal diameter length refers to a diameter length achieved in an equal diameter process through the up-pulling method. The crystal density can be within a range of 7-7.4 g/cm³. The luminous center wavelength of the crystal can be 7420 nm. The light output can reach 35000 ph/MeV and above. The energy resolution can be 7≤9%. The minimum decay time can reach 35 nS and below. The crystal has excellent comprehensive performance.

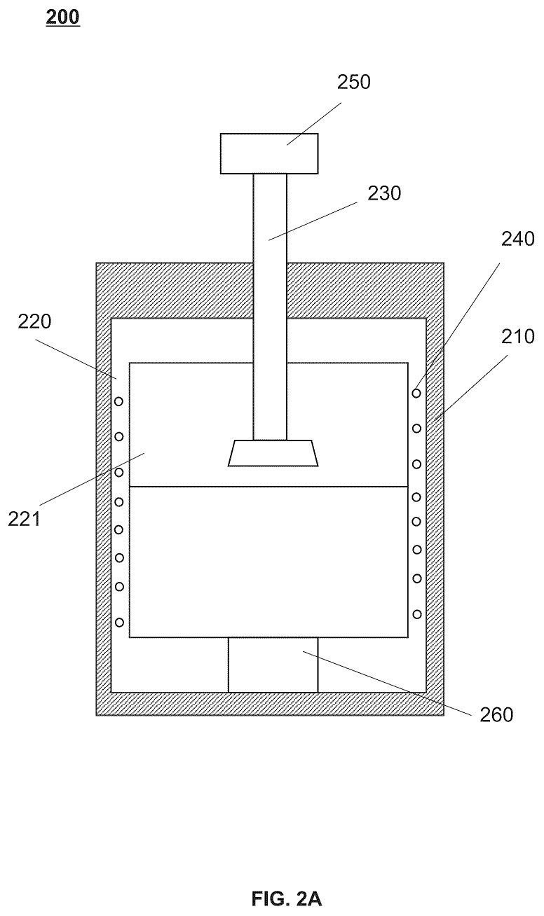

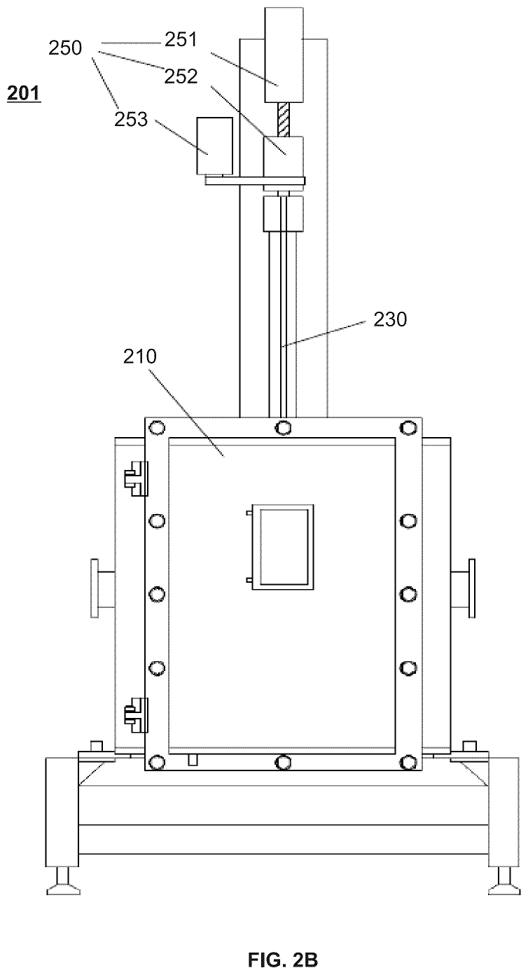

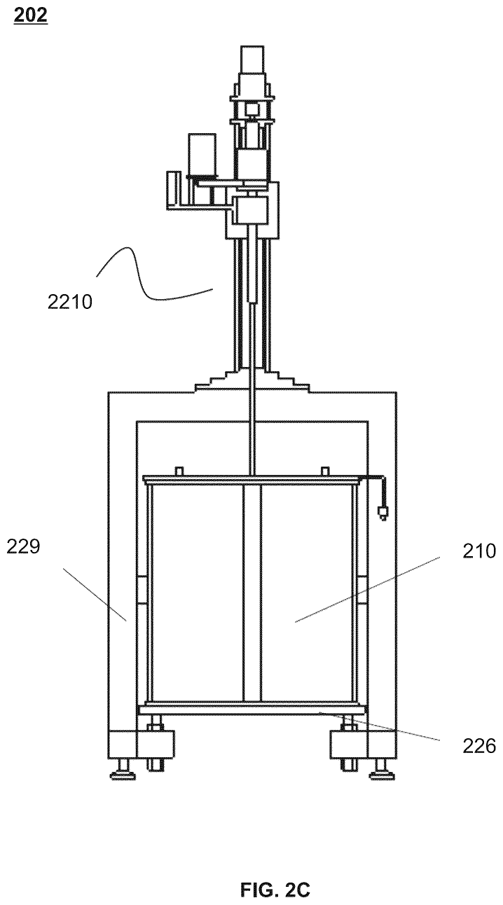

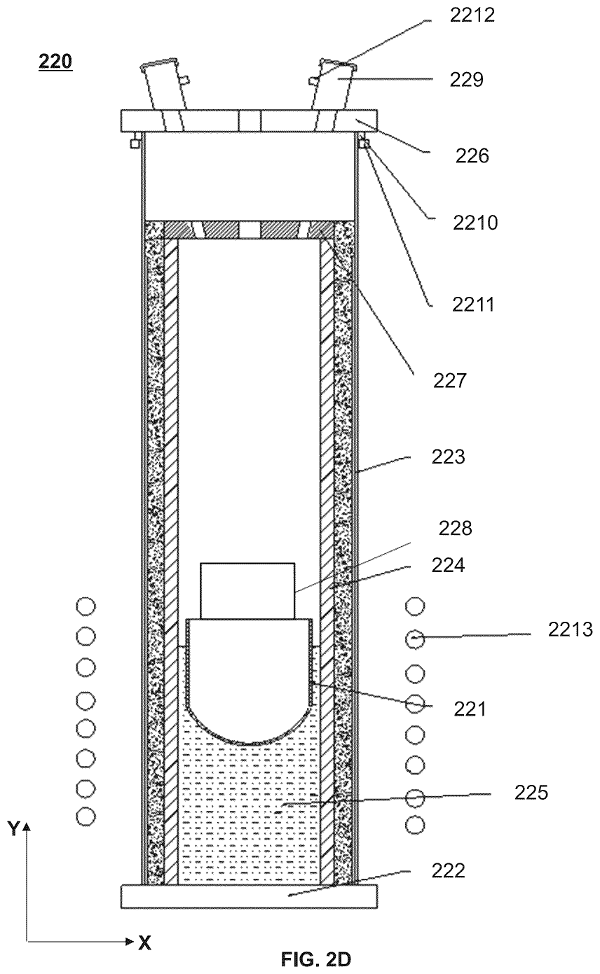

FIG. 2A is a schematic diagram illustrating an exemplary device for preparing a scintillation crystal according to some embodiments of the present disclosure.

In some embodiments, as shown in FIG. 2A, a device 200 for preparing a scintillation crystal may be a single crystal preparation furnace (e.g., a vacuum furnace, an open furnace, etc.). The device for preparing the scintillation crystal may be configured to prepare the scintillation crystals described in any of the above technical solutions. The device 200 for preparing the scintillation crystal may include a furnace chamber 210, a temperature field device 220, a lifting rod 230, a first heating device 240, a first driving device 250, and a crucible 221.

The furnace chamber 210 may be configured to accommodate a plurality of components for preparing the scintillation crystal and provide a place for preparing the crystal. In some embodiments, the furnace chamber 210 may be in the shape of a cylinder, a cube, or a cuboid, etc. In some embodiments, the temperature field device 220 and the first heating device 240 may be disposed in the furnace chamber 210.

The temperature field device 220 may be configured to provide a place and temperature gradient for preparing the scintillation crystal, ensuring the stability of the crystal crystallization process.

In some embodiments, the temperature field device 220 may further include a crucible 221. The crucible 221 may be disposed in the temperature field device 220 for accommodating raw materials for preparing the scintillation crystal. Referring to elsewhere in the present disclosure, the melt may be the raw material for preparing the crystal. In some embodiments, the crucible 221 may be made of various materials, such as an iridium crucible, a molybdenum crucible, etc. In some embodiments, the crucible 221 may rotate around an axis of the crucible 221. In some embodiments, a rotation speed of the crucible 221 may be within a range of 0 rpm-20 rpm.

In some embodiments, a thickness of the crucible 221 may be within a range of 0.8 mm-3 mm. The thickness of the crucible may be within a range of 1 mm-2.5 mm. The thickness of the crucible may be within a range of 1.5 mm-2 mm.

In some embodiments of the present disclosure, by setting the thickness of the crucible 221 to be within the range of 0.8 mm-3 mm, the thickness of the wall of the crucible can be made relatively thin, which is more conducive to heat transfer.

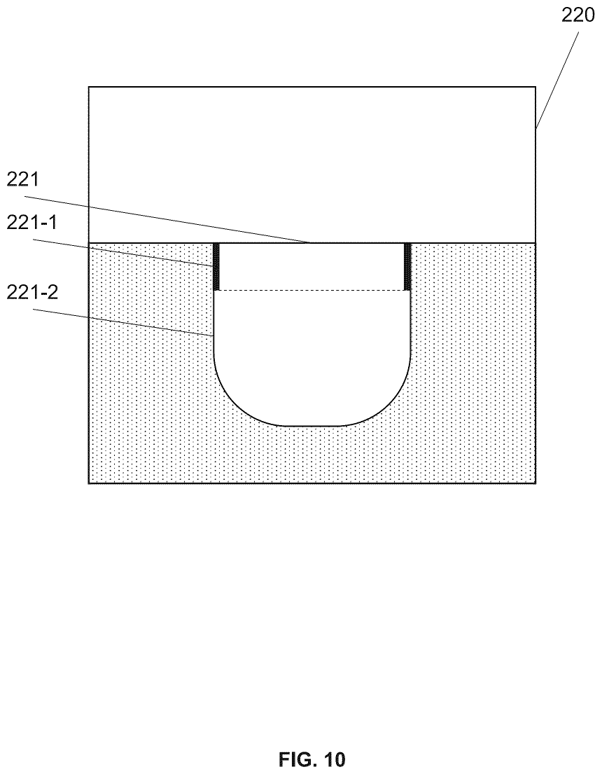

FIG. 10 is a schematic diagram illustrating an exemplary first portion of a crucible wall according to some embodiments of the present disclosure. In some embodiments, as shown in FIG. 10, for a first portion of a crucible wall 221-1 of the crucible, a thickness of the first portion 221-1 may be greater than a thickness of at least a portion of the rest portion of the crucible wall 221-2; and/or the first portion 221-1 may be provided with a reinforcing rib.

The first portion of the crucible wall 221-1 refers to a crucible wall located at a first preset distance below an opening of the crucible. The opening of the crucible refers to an upper opening of the crucible. In some embodiments, the first preset distance may be within a range of 20 mm-40 mm. The first preset distance may be within a range of 24 mm-36 mm. The first preset distance may be within a range of 28 mm-32 mm.

The rest portion of the crucible wall 221-2 refers to a portion of the crucible other than the first portion of the crucible wall 221-1.

In some embodiments, the thickness of the first portion the crucible wall 221-1 may not be greater than 3 mm.

The reinforcing rib refers to a component for increasing the strength of a structure. In some embodiments, the reinforcing rib may be made of various materials, such as steel, glass fiber, carbon fiber, etc. In some embodiments, the material of the reinforcing rib may be the same as that of the crucible. In some embodiments, the reinforcing rib may have various shapes, such as a ring, a rectangle, an X-shape, etc. In some embodiments, the reinforcing rib may have a certain thickness. For example, the thickness of the reinforcing rib may be within a range of 1 mm-1.5 mm.

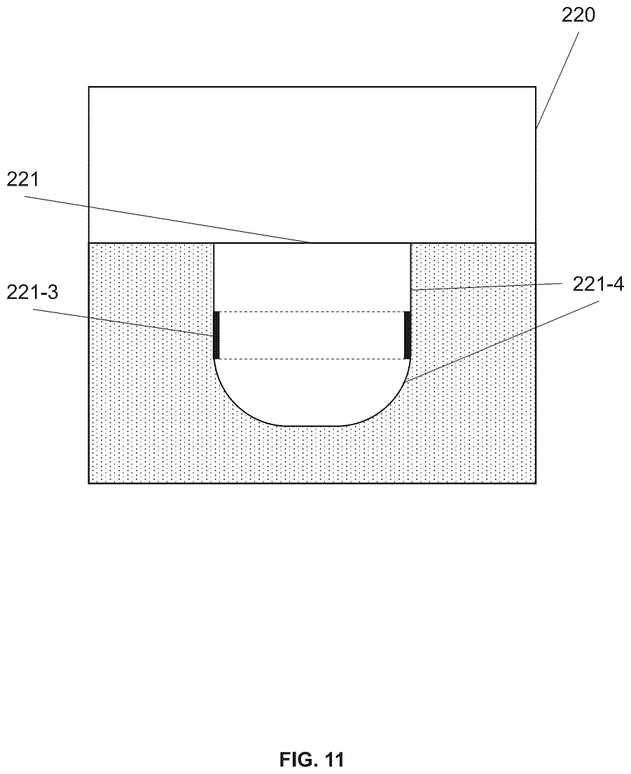

FIG. 11 is a schematic diagram illustrating an exemplary second portion of a crucible wall according to some embodiments of the present disclosure. In some embodiments, as shown in FIG. 11, for a second portion of a crucible wall 221-3 of a crucible, a thickness of the second portion of the crucible wall 221-3 may be greater than a thickness of at least a portion of the rest portion of the crucible wall 221-4; and/or the second portion 221-3 may be provided with a reinforcing rib. More descriptions regarding the reinforcing rib may be found in the related descriptions above, which are not repeated here.

The second portion of the crucible wall 221-3 refers to a crucible wall located at a second preset distance above a bottom of the crucible. The bottom of the crucible refers to a bottom end portion of the crucible. For example, if the bottom of the crucible is an arc-shaped bottom, the bottom of the crucible may include a bottom surface of the crucible and an arc portion above the bottom surface of the crucible (as shown in FIG. 11). In some embodiments, the second preset distance may be within a range of 20 mm-40 mm. The second preset distance may be within a range of 24 mm-36 mm. The second preset distance may be within a range of 28 mm-32 mm.

The rest portion of the crucible wall 221-4 refers to a portion of the crucible other than the second portion of the crucible wall.

In some embodiments, the thickness of the second portion of the crucible wall 221-3 may not be greater than 3 mm.

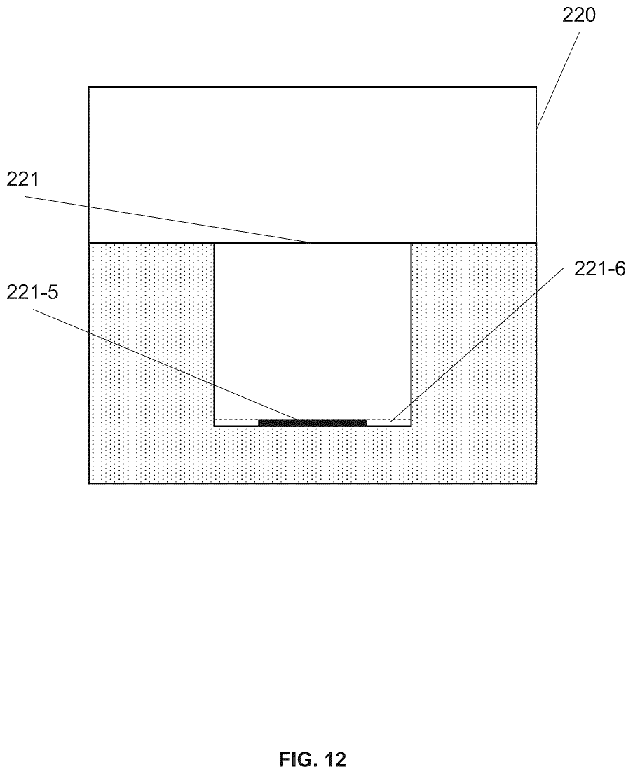

In some embodiments of the present disclosure, the portion of the crucible wall (e.g., the first portion and/or the second portion) that is susceptible to stretching can be reinforced, thereby reducing the risk of cracking and increasing the service life of the crucible.
is a schematic diagram illustrating an exemplary target region of a bottom of a crucible according to some embodiments of the present disclosure. In some embodiments, as shown in FIG. 12, the bottom of the crucible may be a flat bottom, and a thickness of a target region 221-5 on the flat bottom may be greater than a thickness of the rest region 221-6.

The target region 221-5 refers to a region within a preset distance from a center of the flat bottom. The center of the flat bottom refers to a geometric center of the flat bottom of the crucible. In some embodiments, the preset distance may be 30 mm, 40 mm, 50 mm, 60 mm, etc.

The rest region 221-6 refers to a region on the flat bottom of the crucible other than the target region.

In some embodiments, the thickness of the target region 221-5 on the flat bottom may not be greater than 3 mm.

In some embodiments of the present disclosure, the thickness of the target region on the flat bottom is greater than the thickness of the rest region, which can effectively reduce the deformation risk of the central region of the flat bottom and ensure smooth preparation of the scintillation crystal.

In some embodiments, the temperature field device field device 220 may include a filler 225.

The filler 225 may be configured to fix and support other components in the temperature field device to maintain temperature stable and reduce temperature fluctuations, providing a stable temperature field environment. In some embodiments, the filler 225 may include quartz sand, quartz glass, aluminum oxide, zirconium oxide, etc.

In some embodiments, the filler 225 may include zircon sand.

In some embodiments of the present disclosure, the filler includes the zircon sand, which has good thermal insulation performance and can reduce the temperature fluctuations, providing the stable temperature field environment, thereby improving the preparation quality and efficiency of the scintillation crystal.

In some embodiments, the filler 225 may include zirconium fibers.

In some embodiments of the present disclosure, the filler includes the zirconium fibers, such that the thermal insulation performance can be improved, thereby reducing the temperature gradient in the melt, lowering the temperature of the crucible wall, and reducing the deformation of the crucible; meanwhile, the temperature gradient in the vertical direction (e.g., Y direction shown in FIG. 2D) can be increased, which is more conducive to the preparation of the scintillation crystal.

In some embodiments, at least a portion of the crucible 221 may be disposed in the filler 225. For example, as shown in FIG. 2D, a portion of the crucible 221 may be disposed in the filler 225.

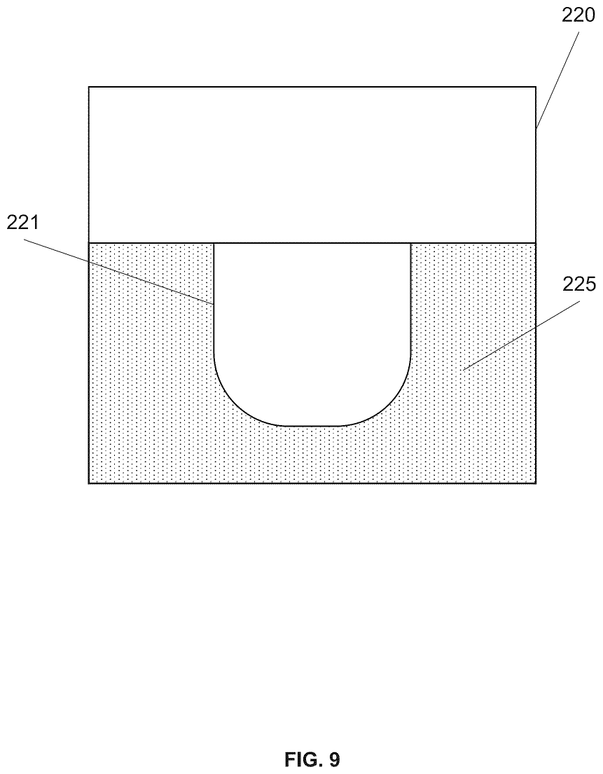

FIG. 9 is a schematic diagram illustrating an exemplary relative position of a crucible and a filler according to some embodiments of the present disclosure. In some embodiments, as shown in FIG. 9, the whole crucible may be disposed in the filler 225.

It is understood that in some embodiments, if the crucible is made thinner, the crucible is more likely to deform after being heated. By disposing the whole crucible in the filler, the crucible can be strongly supported by the filler, making the thinned crucible less likely to deform.

The lifting rod 230 may be configured to provide support and movement control during the preparation process of the crystal. It can be understood that the lifting rod is usually located above the crucible containing a melt, and a seed crystal is provided at a lower end of the lifting rod. By controlling the rotation and lifting movement of the lifting rod, the preparation of the scintillation crystal can be achieved. In some embodiments, a bottom of the lifting rod 230 may be connected with the seed crystal to serve as a seed for preparing the crystal. In some embodiments, at least a portion of the lifting rod 230 may be disposed in the furnace chamber 210.

In some embodiments, the lifting rod 230 may rotate around an axis of the lifting rod 230. In some embodiments, a rotation speed of the lifting rod 230 may be within a range of 0 rpm-20 rpm. In some embodiments, a rotation direction of the lifting rod 230 may be opposite to a rotation direction of the crucible 221.

The first heating device 240 may be configured to provide a temperature required for preparing the scintillation crystal. In some embodiments, the first heating device 240 may be a heating coil (e.g., an induction coil 2213). In some embodiments, the heating coil may have a configuration of inner diameter (250-330 mm)×height (155-270 mm)×(7-9 turns).

The first driving device 250 may be configured to drive the lifting rod to move to make the lifting rod 230 rise or fall, thereby preparing the scintillation crystal by an up-pulling method. In some embodiments, the first driving device 250 may include a motor, a hydraulic cylinder, a pneumatic motor, etc. In some embodiments, the first driving device 250 may be connected with the lifting rod 230 to drive the lifting rod 230 to move along an axial direction of the lifting rod. For example, the first driving device 250 may drive the lifting rod 230 to rotate around the axis of the lifting rod. In some embodiments, the first driving device 250 may be in driving connection (e.g., bolted connection, welded connection, hinged connection, clamping, etc.) with the lifting rod 230 to drive the lifting rod 230 to move.

In some embodiments, the device 200 for preparing the scintillation crystal may further include a second driving device 260. The second driving device 260 may be configured to drive the crucible 221 to rotate around an axis of the crucible. In some embodiments, the axis of the crucible 221 may be parallel to the axis of the lifting rod 230. In some embodiments, the axis of the crucible 221 may coincide with the axis of the lifting rod 230. In some embodiments, the second driving device 260 may include a motor, a hydraulic cylinder, a pneumatic motor, etc.

In some embodiments, a control system of the device 200 for preparing the scintillation crystal may be configured to control a movement direction and/or a movement speed of the first driving device 250 and/or the t.

By providing the second driving device 260 to drive the crucible 221 to rotate, the crucible 221 can be heated more uniform and the reaction can be fully carried out. In addition, the rotation of the crucible 221 can also make the mass transfer of the melt in the crucible more uniform.

In some embodiments, the second driving device 260 may also be configured to adjust a position of the crucible 221, such as a horizonal position and/or a vertical position.

In some embodiments, the device 200 for preparing the scintillation crystal may further include a temperature sensing device and a control device.

The temperature sensing device refers to a sensor capable of sensing a temperature and converting the temperature into a usable output signal, such as a thermocouple sensor, a thermistor sensor, etc. In some embodiments, the temperature sensing device may be disposed on an outer wall of the crucible to obtain a target temperature gradient in real time. The target temperature gradient refers to a temperature gradient that needs to be obtained, such as temperature gradient inside the crucible during the preparation of the scintillation crystal, etc.

The control device refers to a component capable of controlling other components of the device for preparing the scintillation crystal, such as a controller, a processor, a microprocessor, etc. In some embodiments, the control device may be configured to control and adjust various structures and parameters of the device for preparing the scintillation crystal. For example, the control device may be configured to control the first heating device to adjust a heating temperature, etc. In some embodiments, in response to detecting that a difference between a current temperature gradient and an initial temperature gradient is greater than a temperature gradient threshold, the control device may automatically adjust a structure and/or an operation parameter of the device for preparing the scintillation crystal such that a temperature gradient whose difference from the initial temperature gradient is less than the temperature gradient threshold is formed in the device for preparing the scintillation crystal.

The current temperature gradient refers to a temperature gradient in the crucible at a current time of the preparation of the scintillation crystal. The initial temperature gradient refers to a temperature gradient in the crucible at an initial time of the preparation of the scintillation crystal. For example, the initial temperature gradient may be an average of the temperature gradients in a period of time (e.g., 1 min, 2 min, 3 min, 4 min, 5 min, etc.) after the start of the preparation of the scintillation crystal. In some embodiments, the current temperature gradient may be obtained based on a real-time detection result of the temperature sensing device, and the temperature sensing device may record the temperature gradient at the initial time of the preparation of the crystal as the initial temperature gradient. The temperature gradient threshold may be preset based on experience or demand.

In some embodiments, the control device may determine the difference between the current temperature gradient and the initial temperature gradient based on the obtained temperature gradient, and compare the difference with the temperature gradient threshold to determine whether the difference between the current temperature gradient and the initial temperature gradient is greater than the temperature gradient threshold.

In some embodiments, the control device may automatically adjust the structure and/or the operation parameter of the device for preparing the scintillation crystal in various ways, such that a temperature gradient whose difference from the initial temperature gradient is less than the temperature gradient threshold is formed in the device for preparing the scintillation crystal. For example, the control device may automatically adjust the structure and/or the operation parameter of the device for preparing the scintillation crystal according to the current temperature gradient and the initial temperature gradient through a preset rule. The preset rule may be set based on experience or demand. For example, the preset rule may be that when the difference between the current temperature gradient and the initial temperature gradient is greater than the value of the temperature gradient threshold by a, the heating temperature of the first heating device may be adjusted to a*f ° C., wherein f denotes a preset coefficient, which may be preset based on experience or demand.

In some embodiments, the control device may automatically adjust the structure and/or the operation parameter of the device for preparing the scintillation crystal by adjusting the position of a heating component (e.g., the first heating device and/or a second heating device). The position of the heating component may include a horizontal position, a vertical position, etc. The horizontal position refers to a position of the heating component in a horizontal direction (e.g., X direction shown in FIG. 2D). The vertical position refers to a position of the heating component in a vertical direction (e.g., Y direction shown in FIG. 2D). For example, when the difference between the current temperature gradient and the initial temperature gradient is greater than the temperature gradient threshold, the control device may adjust the vertical position of the induction coil 2213 to make the induction coil 2213 closer to the geometric center of the crucible so as to reduce the difference between the current temperature gradient and the initial temperature gradient. As another example, as shown in FIG. 2D, the control device may adjust the vertical position of the second heating device 228 above the crucible 221 to make the second heating device 228 closer to the crucible 221 so as to reduce the difference between the current temperature gradient and the initial temperature gradient.

In some embodiments, the control device may automatically adjust the structure and/or the operation parameter of the device for preparing the scintillation crystal by adjusting the heating power of the heating component (e.g., the first heating device and/or the second heating device). For example, when the difference between the current temperature gradient and the initial temperature gradient is greater than the temperature gradient threshold, the control device may increase the heating power of the induction coil 2213 to reduce the difference between the current temperature gradient and the initial temperature gradient. As another example, as shown in FIG. 2D, the control device may increase the heating power of the second heating device 228 above the crucible 221 to reduce the difference between the current temperature gradient and the initial temperature gradient.

In some embodiments, the control device may automatically adjust the structure and/or the operation parameter of the device for preparing the scintillation crystal by adjusting the position of the crucible. The position of the crucible may include a horizontal position, a vertical position, etc. The horizontal position refers to a position of the crucible in a horizontal direction (e.g., X direction shown in FIG. 2D). The vertical position refers to a position of the crucible in a vertical direction (e.g., Y direction shown in FIG. 2D). For example, when the difference between the current temperature gradient and the initial temperature gradient is greater than the temperature gradient threshold, the control device may adjust the vertical position of the crucible by controlling the second driving device to make the crucible closer to the geometric center of the induction coil 2213, and increase a contact area between the crucible and the filler, so as to reduce the difference between the current temperature gradient and the initial temperature gradient.

In some embodiments, a specific adjustment scheme may be obtained in various ways, such as a preset rule, a preset algorithm, a machine learning model, etc., such that a temperature gradient whose difference from the initial temperature gradient is less than the temperature gradient threshold is formed in the device for preparing the scintillation crystal, and the energy consumption required for adjustment is low.

In some embodiments of the present disclosure, automatically adjusting the structure and/or the operation parameter of the device for preparing the scintillation crystal may include at least one of the following: adjusting the position of the first heating device; adjusting the heating power of the first heating device; adjusting the position of the crucible; adjusting a position of the second heating device; and adjusting a heating power of the second heating device. The temperature gradient can be effectively adjusted in various ways to avoid the inaccuracy caused by a single adjustment way.

It is understood that in an ideal condition, it is desired that the temperature gradient in the vertical direction at a preparation interface can remain constant. However, as the crystal grows, the temperature gradient changes. For example, as the crystal continues to grow, the heat dissipated by the crystal increases with the increase in the length of the crystal, affecting the temperature gradient. In some embodiments of the present disclosure, the device for preparing the scintillation crystal may further include: the temperature sensing device, disposed on the outer wall of the crucible and configured to obtain the target temperature gradient in real time; the control device, configured to automatically adjust the structure and/or the operation parameter of the device for preparing the scintillation crystal in response to detecting that the difference between the current temperature gradient and the initial temperature gradient is greater than the temperature gradient threshold, such that a temperature gradient whose difference from the initial temperature gradient is less than the temperature gradient threshold is formed in the device for preparing the scintillation crystal, and the temperature gradient change can be monitored in real time, and the intelligent and automatic adjustment can be performed to avoid the quality problem in the preparation of the crystal caused by an excessive change in the temperature gradient.

The definition of some terms in the description in connection with FIGS. 2B and 2C can be used as the definition of the same terms in the description in connection with FIG. 2A.

The furnace body of the device 200 for preparing the scintillation crystal may be a vacuum furnace 201 or an open furnace 202. The vacuum furnace 201 may be understood as a furnace chamber that is completely vacuumed, making no gas exchange between the device inside the furnace chamber and the atmospheric environment. More descriptions regarding the relevant structure of the vacuum furnace 201 may be found in FIG. 2B and related descriptions thereof. The open furnace 202 may be understood as a furnace chamber that can be opened. An operator (e.g., a worker, or an engineer) may directly observe the temperature field device 220 in the furnace. More descriptions regarding the relevant structure of the open furnace 202 may be found in FIG. 2C and related descriptions thereof.

FIG. 2B is a schematic structural diagram illustrating an exemplary vacuum furnace according to some embodiments of the present disclosure. As shown in FIG. 2B, the vacuum furnace 201 may include the furnace chamber 210, the lifting rod 230, the first driving device 250, a temperature field device (not shown in the figure), a crucible (not shown in the figure), and a first heating device (not shown in the figure). More descriptions regarding the furnace chamber 210, the lifting rod 230, and the crucible may be found in the related descriptions of FIG. 2A, which are not repeated here. In some embodiments, the first driving device 250 may include a lifting assembly 251, a rotating assembly 252, and a weighing device 253, and may be located at a top of the furnace chamber 210. The first driving device 250 may be configured to drive the lifting rod 230 to rotate around an axis of the lifting rod through the rotating assembly 252.

In some embodiments, the weighing device 253 may be configured to detect a weight of the crystal on the lifting rod 230. In some embodiments, a control system of the vacuum furnace may be in signal connection with the weighing device 253 to receive an output signal of the weighing device 253. In some embodiments, the output signal of the weighing device 253 may be a weight signal of the crystal on the lifting rod 230. In some embodiments, the output signal of the weighing device 253 may be output through a mercury slip ring. By receiving the output signal of the weighing device, the control system may determine the weight of the crystal, an increase rate of the weight of the crystal, and other information, and then determine a crystallization speed of the crystal. According to the crystallization speed of the crystal, the control system may further determine the temperature of a temperature field and send a control signal to a power management portion of a heating coil to control the temperature of the temperature field. Meanwhile, the control system may control a movement direction and/or a movement speed of the lifting assembly 251 and/or the rotating assembly 252 according to the requirements of the preparation process parameters of the crystal, thereby realizing automatic control of the preparation of the crystal.

In some embodiments, the temperature field device may include a crucible and an alumina pipe (not shown in the figure). The alumina pipe may be arranged vertically and concentrically outside the crucible to keep the temperature around the crucible stable and heat a material in the crucible evenly. In some embodiments, the alumina pipe may be replaced with a zirconia pipe. In some alternative embodiments, the zirconia pipe may sleeve the alumina pipe, or the alumina pipe may sleeve the zirconia pipe. The alumina pipe and the zirconia pipe may be arranged concentrically outside the crucible. In some embodiments, the zirconia pipe may also be replaced with a hollow cylinder composed of a zirconia brick.

In some embodiments, the first heating device may be arranged vertically and concentrically with the crucible and the alumina pipe, and located outside the alumina pipe.

In some embodiments, the vacuum furnace 201 may include a vacuum device (not shown in the figure). The vacuum device may be configured to provide a vacuum constant pressure environment inside the furnace chamber 110, such as a vacuum constant pressure environment with a pressure of 1000 Pa-0.5 MPa. In some embodiments, the vacuum device may include a vacuum pump and an inert gas cylinder. By evacuating with the vacuum pump or evacuating with the vacuum pump and replacing the air in the furnace chamber with flowing gas, the interior of the furnace chamber can be in the vacuum constant pressure environment to complete the preparation process of the crystal. In some embodiments, the flowing gas may be a mixed gas of one or more of an inert gas, carbon monoxide, carbon dioxide, oxygen, etc.

FIG. 2C is a schematic structural diagram illustrating an open furnace according to some embodiments of the present disclosure. As shown in FIG. 2C, the open furnace 202 may include a furnace frame 229, the furnace chamber 210, a first bottom plate 226, and a movement device 2210.

The furnace frame 229 may be configured to mount different components of the open furnace 202, including the furnace chamber 210, the first bottom plate 226, the movement device 2210, etc. For example, the furnace chamber 210 may be disposed on the furnace frame 229 by bolted connection, welded connection, or hinged connection. In some embodiments, the dimensions of the furnace frame 229 may be 1000 mm-1400 mm in length, 750 mm-1000 mm in width, and 1100 mm-1800 mm in height.

The furnace chamber 210 may be a cylinder, a cube, etc., for providing a space for the preparation of the crystal. In some embodiments, the furnace chamber 210 may include components such as a furnace body and a furnace cover. The furnace cover may be disposed on the furnace body.

In some embodiments, the open furnace 202 may include the temperature field device 220 (see FIG. 2D), a lifting rod assembly, a heat source, and other components. A first through hole may be provided on the furnace cover. The first through hole may be configured to accommodate the temperature field device. In some embodiments, a height of the temperature field device may be greater than a height of the furnace cover, i.e., a portion of the temperature field device may be disposed in the furnace chamber 210, and another portion of the temperature field device may be disposed outside the furnace chamber 210. In some embodiments, the height of the temperature field device may not be greater than the height of the furnace cover (e.g., an upper end surface of the temperature field device may be on the same level with the furnace cover or may be lower than the furnace cover), i.e., the whole temperature field device may be disposed inside the furnace chamber 210. The temperature field device may include a sealing cylinder, a cover plate disposed at a top of the sealing cylinder, and a bottom plate disposed at a bottom of the sealing cylinder. A second through hole may be provided on the cover plate. The lifting rod assembly may extend into the temperature field device through the second through hole. A through hole for passing gas may also be provided on the cover plate. More descriptions regarding the structure of the temperature field device 220 may be found in FIG. 2D and related descriptions thereof.

In some embodiments, the furnace chamber 210 may be set as a non-sealed structure, i.e., after the temperature field device 220 is placed in the first through hole set on the furnace cover, the furnace cover and the outer wall of the temperature field device may not be sealed, which is conducive to saving the manufacturing and maintenance cost, and ultimately reducing the production cost.

The first bottom plate 226 may be configured to carry components such as the furnace chamber 210, the temperature field device 220, and the heat source. In some embodiments, the first bottom plate 226 may be a portion of the furnace body, i.e., the furnace body may include components such as a side wall and the first bottom plate 226.

In some embodiments, the movement device 2210 may include a lifting assembly, a weighing assembly, and a rotating assembly. The lifting assembly may be fixed on the furnace frame 229. The lifting assembly may include a first drive device for controlling the lifting rod 230 to move vertically. The weighing assembly may be configured to determine a weight of the crystal on the lifting rod assembly. The rotating assembly may be configured to control the rotation of the lifting rod.

FIG. 2D is a schematic diagram illustrating the temperature field device 220 of an open furnace according to some embodiments of the present disclosure. In some embodiments, the temperature field device 220 may also be used in the vacuum furnace 201.

In some embodiments, the temperature field device 220 of the open furnace 202 may include the crucible 221, a bottom plate 222, a first cylinder 223, a second cylinder 224, the filler 225, a second cover plate 227, the second heating device 228, and the induction coil 2213. During use, the temperature field device 220 may be placed in the open furnace of the device 200 for preparing the scintillation crystal and located in the induction coil 2213 inside the furnace. The crucible 221 may be placed inside the open furnace, and the heating body 228 may be placed directly above the crucible 221.

The bottom plate 222 may be disposed at a bottom of the temperature field device, and configured to carry other components of the temperature field device, such as the first cylinder 223, the second cylinder 224, and/or the filler 225. In some embodiments, a material of the bottom plate 222 may include a heat-reflecting material with a high reflectivity, such as gold, copper, plated metal, stainless steel, etc. In some embodiments, a diameter of the bottom plate 222 may be within a range of 200-500 mm and a thickness of the bottom plate 222 may be within a range of 10-40 mm. Since the temperature field device is placed inside the furnace chamber of the device 200 for preparing the scintillation crystal during use, the bottom plate 222 may be placed or mounted on a mounting plate of the furnace body, wherein the mounting mode may include welding, riveting, bolting, bonding, etc. During mounting, the level of the bottom plate 222 may be less than 0.5 mm/m. In some embodiments, a circulation coolant passage may be provided on the bottom plate 222, and a circulation coolant may be introduced to absorb the heat inside the temperature field device for heat insulation and heat radiation reduction. The circulation coolant passage may be disposed inside the bottom plate 222 in a spiral shape. The coolant used may include water, ethanol, or the like, or any combination thereof. One or more circulation coolant passages may be provided. A diameter of the circulation coolant passage may be within a range of 5-25 mm.

The first cylinder 223 may be mounted on the bottom plate 222 to form an outer wall portion of the temperature field device. The bottom plate 222 may cover an open end of the first cylinder 223. The first cylinder 223 may be mounted on the bottom plate 222 by welding, riveting, etc. to support the whole temperature field device. A manufacturing material of the first cylinder 223 may include zirconium oxide, graphite, etc. During mounting, a concentricity of the first cylinder 223 and the bottom plate 222 may be less than 1 mm, and a verticality of the first cylinder 223 and the bottom plate 222 may be less than 0.2 degrees. An inner diameter of the first cylinder 223 may be within a range of 180-450 mm, and a height of the first cylinder 223 may be within a range of 600-1600 mm based on the size of the bottom plate 222.

The second cylinder 224 may be disposed inside the first cylinder 223. In some embodiments, a manufacturing material of the second cylinder 224 may include zirconium oxide, aluminum oxide, etc. In order to match the size of the first cylinder 223, an inner diameter of the second cylinder 224 may be within a range of 70-300 mm and a thickness of the second cylinder 224 may be within a range of 8-30 mm. In some embodiments, one end of the second cylinder 224 may be placed or mounted on the bottom plate 222 by, for example, riveting, snap-fitting, etc. During mounting, a concentricity of the second cylinder 224 and the bottom plate 222 may be less than 1 mm, and a verticality of the second cylinder 224 and the bottom plate 222 may be less than 0.2 degrees.

The filler 225 may fill in the second cylinder 224, and/or fill in a gap between the first cylinder 223 and the second cylinder 224. The filler 225 may be used for heat preservation. In some embodiments, by changing the height and the tightness of the filler 225, different stable temperature gradients may be obtained to meet different preparation requirements of the crystal. The height of the filler 225 may determine a position of a heating center, which can affect a temperature gradient above a melt interface in a vertical direction. The particle size and the tightness of the filler 225 affect the heat preservation ability of the filler 225 (the smaller the particle size, the tighter the filling, the stronger the heat preservation ability, and the more stable the temperature), which can affect a temperature gradient below the melt interface in the vertical direction. Different filling heights, particle sizes and tightness may correspond to different temperature gradients. In some embodiments, the filler 225 may be a granular, brick-shaped, and/or felt-shaped material made of a high temperature resistant material, including zircon sand (a zirconium silicate compound), zirconium oxide particles, aluminum oxide particles, etc. The particle size of the filler 225 may be within a range of 5-200 mesh.

In some embodiments, the filler 225 filling in the second cylinder 224 may be configured to support the crucible 221 containing reaction materials for the preparation of the crystal.

The second heating device 228 may be disposed directly above the crucible 221. In some embodiments, the second heating device 228 may be configured to reduce the temperature gradient above the crucible 221. A height or an inner diameter of the second heating device 228 may provide the crystal with a temperature required for annealing when the crystal passes through the second heating device 228 from a seed crystal, so as to simultaneously anneal the crystal during the preparation process of the crystal. In some embodiments, the second heating device 228 may be made of iridium metal (Ir), platinum metal (Pt), etc. In some embodiments, an outer diameter of the second heating device 228 may be within a range of 60-260 mm, the inner diameter of the second heating device 228 may be within a range of 100-180 mm, a thickness of the second heating device 228 may be within a range of 2-10 mm, and the height of the second heating device 228 may be within a range of may be 2-200 mm.

The preparation of the crystal may require a large temperature field temperature gradient, but a large temperature gradient may easily cause the crystal to crack. To balance the relationship between the preparation of the crystal and the temperature gradient, the second heating device may be additionally disposed above the crucible to reduce the temperature gradient above the crucible and increase a temperature gradient at a solid-liquid interface.

In some embodiments, the crucible 221 may be made of iridium metal (Ir), molybdenum metal (Mo), etc., and may have a diameter of 60-250 mm, a thickness of 2-4 mm, and a height of 60-250 mm. In some embodiments, the crucible 221 may be used as a heating device to melt the reaction materials included therein to facilitate subsequent preparation of the crystal. When an alternating current (AC) of a certain frequency is passed through an induction coil (e.g., the induction coil 2213) surrounding the outer wall of the first cylinder 223, an alternating magnetic field may be generated around the first cylinder 223, and a closed induced current is generated in a conductor (e.g., the crucible 221) through electromagnetic induction, and the electrical energy may be converted into thermal energy to increase the temperature of the conductor to achieve melting. The induction coil 2213 may have 5-14 turns of coil, an induction frequency of the induction coil 2213 may be within a range of 2 kHz-15 kHz, and an induction rated power of the induction coil 2213 may be within a range of may be 20-60 KW. An inner diameter of the cylinder surrounded by the induction coil 2213 may be within a range of 180-430 mm, and a height of the cylinder surrounded by the induction coil 2213 may be within a range of 180-330 mm. In some embodiments, a filling height of the filler 225 may cause a vertical spacing between an upper edge of the crucible 221 and an upper edge directly behind the induction coil 2213 to be within a range of 0-50 mm. “−” indicates that the upper edge of the crucible is lower than the upper edge of the induction coil, and “+” indicates that the upper edge of the crucible is higher than or equal to the upper edge of the induction coil. Preferably, the vertical spacing between the upper edge of the crucible 221 and the upper edge of the induction coil 2213 may be within a range of 5-45 mm.

The first cover plate (not shown in the figure) may be disposed at a top of the temperature field device, and configured to cooperate with other components to seal the temperature field device. In some embodiments, the first cover plate may cover the other open end of the first cylinder 223, and may be connected by welding, riveting, etc. In some embodiments, a material of the first cover plate may be the same as that of the bottom plate 222. In some embodiments, a diameter of the first cover plate may be within a range of 200-500 mm and a thickness of the first cover plate may be within a range of 10-40 mm. In some embodiments, the first cover plate may include at least two first through holes for passing protective gas. In some embodiments, the protective gas may include an inert gas. The inert gas may include nitrogen, helium, radon, etc. Based on the nature and the size of a target crystal to be prepared, a flow rate of the protective gas introduced into the temperature field device may be within a range of 1-30 liters/min.

In some embodiments, an observation member (not shown in the figure) may be provided on each of the at least two first through holes. Since the preparation cycle of the crystal is too long (e.g., as long as 4-40 days), a device for observing an internal situation may be provided above the temperature field device, and a user (e.g., a factory worker) may check the preparation of the crystal through the device. If an abnormal situation is found, measures may be taken in time. The observation member may be a tubular device of which one end is closed and the other end is open. An observation window may be provided at a top of the observation member, which is made of a transparent material such as polystyrene (PS) and polycarbonate (PC).

In some embodiments, the first cover plate may also be provided with a circulation coolant passage. More descriptions regarding the circulation coolant passage may be found in the circulation coolant passage disposed on the bottom plate 222.

The second cover plate 227 may be disposed inside the first cylinder 223, and cover an open end of the second cylinder 224 close to the first cover plate, and may be connected with the second cylinder 224 by welding, riveting, etc. In some embodiments, in order to clearly obtain the internal situation of the temperature field device from the outside, at least two second through holes corresponding to the at least two first through holes on the first cover plate may be provided on the second cover plate 227. In some embodiments, a thickness of the second cover plate 227 may be within a range of 20-35 mm.

A sealing ring (not shown in the figure) and a pressure ring (not shown in the figure) may achieve the sealing between the first cylinder 223 and the first cover plate. In some embodiments, the sealing ring may be configured at a connection between the first cylinder 223 and the first cover plate, and may be made of a material with a certain elasticity, such as silicone or rubber. In some embodiments, an inner diameter of the sealing ring may be within a range of 170-540 mm, and a line diameter of the sealing ring may be within a range of 5-10 mm.

The pressure ring may provide the effect of fixing and compressing to the sealing ring. In some embodiments, a shape of the pressure ring may match the first cylinder 223, and an inner diameter of the pressure ring may be slightly greater than the outer diameter of the first cylinder 223. In this way, the pressure ring may sleeve the first cylinder 223 and move. In some embodiments, an outer diameter of the pressure ring may be within a range of 200-500 mm, the inner diameter of the pressure ring may be within a range of 190-460 mm, and a thickness of the pressure ring may be within a range of 8-15 mm.

In some embodiments, the temperature field device may further include a gas passage (not shown in the figure). The gas passage may be provided on the observation member and configured to connect a vent pipe and/or an outlet pipe to introduce the protective gas into the temperature field device. More descriptions regarding the protective gas may be found in FIG. 3 and related descriptions thereof.

Raw materials required for preparing the crystal may be placed in the crucible 221 for reaction after being weighed and pretreated according to a reaction formula. Different crystals may have different preparation conditions, such as different temperature gradients. In this case, an amount and a tightness of the filler 225 may be changed to adjust to a required temperature gradient. For example, the amount of the filler 225 may determine a relative position of the crucible 221 and the induction coil 2213, and then determine a heating center of the entire temperature field. Meanwhile, the higher the compactness of the filled filler 225, the better the heat preservation effect, the better the stability of the formed temperature field, and the more conducive to the preparation of the crystal. After the amount, the particle size and the tightness of the filler 225 are determined, other components may be assembled for sealing. After all components are assembled, gas may be introduced into the temperature field device, and an auxiliary device such as a cooling circulation pump may be started to introduce a coolant into the circulation coolant passage in the bottom plate 222 and the first cover plate. Then, the device 200 for preparing the scintillation crystal (including the temperature field device) may be started to prepare the crystal. The gas introduced into the temperature field device may enter from one or more first through holes (e.g., first enter from one or more gas passages). The gas discharged from the temperature field device may be discharged from the rest first through holes (e.g., finally discharged from one or more gas passages). After the temperature is appropriate, an automatic control program may be started to enter an automatic preparation mode, and the preparation of the scintillation crystal may be completed after several days (e.g., 4-40 days, etc.) through the process of neck growth, crown growth, diameter equalizing, finishing, cooling, etc.

It is understood that the preparation of the crystal may require a large temperature field temperature gradient, but the large temperature gradient may easily cause the crystal to crack.

According to the device for preparing the scintillation crystal provided in some embodiments of the present disclosure, the open furnace and the flowing atmosphere heat exchange temperature field device, the temperature gradient of the solid-liquid interface is increased, and the second heating device is additionally disposed above the crucible to reduce the temperature gradient, which can effectively solve the problem of high stress and easy cracking of the crystal due to poor symmetry of the temperature field and inappropriate temperature gradient during the preparation of the crystal, thereby providing a good preparation environment for the preparation of the scintillation crystal. In addition, the volatilization of SiO₂ is suppressed by the temperature field airflow pressure, and oxygen is allowed to enter the furnace body at the same time, which can alleviate the problem of poor consistency of the crystal performance caused by component deviation during the preparation process and the problem of oxygen vacancies formed due to lack of oxygen during the preparation process in the vacuum furnace.

In some embodiments, the description of the device for preparing the scintillation crystal in FIG. 2A may also be applied to FIGS. 2B and 2C. For example, the description of the crucible, the filler, the temperature sensing device, and the control device in FIG. 2A may also be applied to FIGS. 2B and 2C.

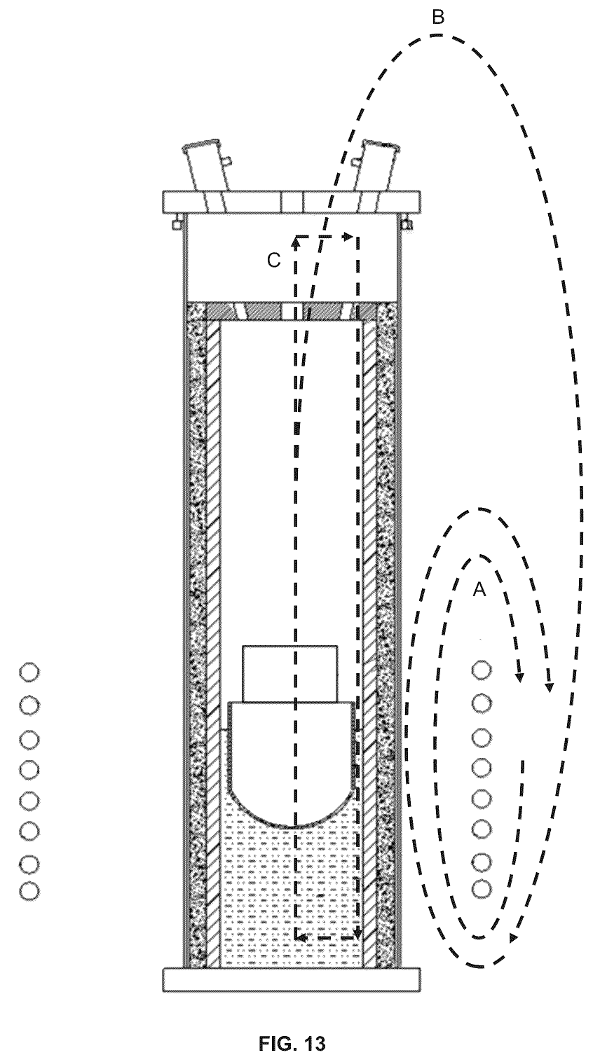

FIG. 13 is a schematic diagram illustrating an exemplary convection loop according to some embodiments of the present disclosure. In some embodiments, the temperature field device 220 may be configured to make heat generated in the preparation of the scintillation crystal form at least one convection loop. The convection loop refers to a loop in which heat flows due to a difference in temperature, usually from higher heat to lower heat. The temperature field device 220 may cause the heat in the preparation process to form at least one convection loop between at least two of the temperature field device, the first heating device, and the furnace chamber, such as loops A-C in FIG. 13. The loop A is a convection loop formed by the heat around the first heating device (e.g., the induction coil), which is caused by the thermal radiation from the temperature field device 220. For example, the heat may form the convection loop A between an outer wall of the temperature field device 220 (e.g., the first cylinder 223) and an inner wall of the furnace chamber 210. The loop B refers to a convection loop formed by the heat between the temperature field device and the first heating device. The heat may flow upward from the center of the temperature field device (e.g., the crucible), flow out of the temperature field device 220 through the second cover plate 227 and the first bottom plate 226, and then flow along the inner wall of the furnace chamber 210 and the outer wall of the temperature field device 220 (i.e., flow around the first heating device after flowing out of the center of the temperature field device) to form the loop B. The loop C refers to a convection loop formed by the he inside the temperature field device. The heat may flow upward from the center of the temperature field device (e.g., the crucible), pass through the second plate 227, and then flow downward along the first bottom plate 226 through the inner wall (e.g., the second cylinder 224) of the temperature field device 220 (e.g., the second cylinder 224) along the first bottom plate 226, and flow from the bottom plate 222 to the center of the temperature field device to form the loop C.

It is understood that the temperature field structure may make the heat generated during the preparation of the scintillation crystal form at least one convection loop between at least two of the temperature field device, the first heating device, and the furnace chamber with the heat in the reaction process. The at least one convection loop can reduce the volatilization of reactants, and increase heat transfer (i.e., increase the temperature gradient), thereby improving the preparation consistency of the crystal.

FIG. 3 is a flowchart illustrating an exemplary method for preparing a scintillation crystal according to some embodiments of the present disclosure. In some embodiments, a process 300 may be performed by the device 200 for preparing the scintillation crystal. As shown in FIG. 3, the process 300 may include the following operations.

In 310, reaction materials may be weighed according to a molar ratio based on a reaction equation.

The reaction equation of the scintillation crystal may be as follows:

$$( 1 - x - m - z ) {Lu}_{2} {O}_{3} + {zY}_{2} {O}_{3} + {ySc}_{2} {O}_{3} + {ySc}_{2} {O}_{3} + \frac{n}{3} {CeCl}_{3} + ( 2 x - \frac{n}{2} ) {CeO}_{2} + 2 sCaO + {SiO}_{2} = {Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} + \frac{( x - s - \frac{n}{2} )}{2} {O}_{2} ,$$

wherein, x=0.0000001-0.06, 0<s<0.05, 0≤y<1, 0≤z<1, 0<n<10. More descriptions regarding x, y, z, s, and n may be found in FIG. 1 and related descriptions thereof.

In some embodiments, before the reaction materials are weighed, a first pretreatment may be performed on the reaction materials in the reaction equation.

In some embodiments, the first pretreatment may include high temperature calcination. It is understood that in order to remove other substances included in the reaction materials, such as water and organic substances of other metal elements (including cerium, gallium, aluminum, gadolinium, etc.) as much as possible to make the reaction materials purer, all the reaction raw materials may be subjected to high temperature calcination to achieve the purpose of removing water and other organic substances. A commercially available high temperature calcination device may be used to achieve the calcination of the reaction materials, such as a muffle furnace. In some embodiments, a calcination temperature of the reaction materials may be within a range of 100° C.-1400° C. Depending on the properties of different reaction materials, the time of high temperature calcination may not be less than 5 h.

The purity of the reaction materials has a great influence on the scintillation performance of the scintillation crystal. Accordingly, in order to make the final scintillation crystal meet the requirements, the purity of CeO₂ and Lu₂O₃ in the reaction materials used to prepare the scintillation crystal may be greater than 99.99%, and the purity of SiO₂ and Y₂O₃ in the reaction materials may be greater than 99.999%.

In some embodiments, after the first pretreatment is performed on the reaction materials in the reaction equation, when the reaction materials are naturally cooled to 35° C., the reaction materials may be weighed by a weighing instrument such as an analytical balance or a macroanalytical balance in the molar ratio.

It is understood that during the preparation process of the crystal, silicon dioxide (SiO₂) is easily volatilized under a heating condition, which may cause component deviation of the finally generated crystal, and cause different crystal compositions obtained each time, resulting in poor repeatability. In some embodiments, an actual weight of silicon dioxide may exceed a theoretical weight of silicon dioxide by 0.001%-10%. The actual weight refers to a weight actually weighed, and the theoretical weight refers to a weight calculated based on the molar ratio, i.e., after the silicon dioxide is weighed in the molar ratio, an additional excess of 0.001%-10% of the already weighed weight may be added. By adding excess silicon dioxide to the reaction materials, the problem of component deviation and poor preparation repeatability caused by the volatilization of the raw materials can be suppressed to a certain extent.

In some embodiments, a second pretreatment may be performed on the weighed reaction materials.

In some embodiments, the second pretreatment may include mixing the reaction materials at a room temperature. In some embodiments, the second pretreatment may include heating the reaction materials to a preset temperature and mixing the heated reaction materials.

It is understood that the uniformly mixed reaction materials are conducive to subsequent preparation of the crystal. A mixing device used may be a three-dimensional motion mixer, a double cone mixer, a vacuum mixer, a plow mixer, a V-type mixer, a conical twin-screw spiral mixer, a planetary mixer, a horizontal screw mixer, etc.

In some embodiments, the reaction materials may be mixed uniformly at the room temperature by the mixing device; or the reaction materials may be heated to the preset temperature and the heated reaction materials may be mixed uniformly. The preset temperature may be less than 1200° C. The mixing time of the reaction materials may be within a range of 0.5-48 h.

In some embodiments, the second pretreatment may include pressing. The pressing refers to applying a certain pressure to the reaction materials to transform the reaction materials from a dispersed state into an embryo with an original shape, such as a cylindrical shape. The pressed reaction materials may have a smaller volume than the dispersed state, and may be easier to put into a reaction place (e.g., a reaction crucible), such that the reaction materials may be loaded at one time. Meanwhile, the air included in the dispersed reaction materials may be discharged after pressing to prevent influencing the preparation of the crystal in subsequent reactions. A device for realizing the pressing may be an isostatic press, such as a cold isostatic press. The reaction materials may be loaded in a press tank and then pressed into the shape. The pressure used during the pressing may be within a range of 100-300 MPa.

In some embodiments of the present disclosure, after the first pretreatment is performed on the reaction materials in the reaction equation, the reaction materials are weighed in the molar ratio; the second pretreatment is performed on the weighed reaction materials; and the scintillation crystal is prepared using the up-pulling method to generate the scintillation crystal with larger size and fewer macroscopic defects, which has excellent optical properties, preparation repeatability of the crystal, performance consistency of the crystal, etc., and can be widely used in a plurality of fields. By introducing the protective gas, the temperature gradient of the temperature field is improved, the contamination of the melt by volatiles is reduced, the possibility of iridium volatilization into the melt is reduced, and the preparation stability of the crystal is improved. By using an appropriate amount of excess SiO₂, the component deviation of the scintillation crystal can be avoided, and the problem of Ce doping concentration deviation under different process conditions can be effectively solved, such that the preparation repeatability of the crystal is good. By optimizing the process parameters of the preparation process of the crystal, the quality of the crystal can be consistent during each preparation process.

In 320, a scintillation crystal may be prepared using the weighed reaction materials.

In some embodiments, the scintillation crystal may be prepared through the device 200 for preparing the scintillation crystal using the weighed reaction materials. More descriptions regarding the single crystal preparation furnace and the temperature field device may be found in FIGS. 2A-2C and related descriptions thereof.

In some embodiments, before the crystal is prepared, an assembly process of the device 200 for preparing the scintillation crystal needs to be completed.

In some embodiments, the assembly process may include pre-assembly treatment of at least one component of the device for preparing the scintillation crystal. In some embodiments, the at least one component of the device for preparing the scintillation crystal may include a crucible. In some embodiments, the pre-assembly treatment may include one or more of coating protection, acid washing, and foreign matter cleaning. The coating protection refers to adding a high temperature coating material to the entire outer surface of the crucible, such as polyamide silicone, etc. The crucible treated with the coating protection may isolate or reduce the contact between oxygen and a crucible surface, i.e., to avoid or reduce the impact of crucible oxidation and oxides thereof on the crystal when the crystal is prepared in a high-temperature and oxygen-rich environment. In some embodiments, after the crucible is subjected to the coating protection, the crucible may also be subjected to the acid washing. For example, an inner wall of the crucible may be immersed with acid. In some embodiments, the acid may include an organic acid and/or an inorganic acid. An exemplary organic acid may include one or more of a carboxylic acid (e.g., a formic acid, an oxalic acid, etc.), a sulfonic acid (e.g., an ethanesulfonic acid, a benzenesulfonic acid, etc.), a sulfinic acid, etc. An exemplary inorganic acid may include one or more of a hydrochloric acid, a sulfuric acid, a nitric acid, a phosphoric acid, or the like, or any combination thereof. In some embodiments, a concentration of the acid may be within a range of 1%-15%. An acid immersion treatment time may be within a range of 0.1-10 h. After the immersion is completed, the crucible may be cleaned with pure water and dried. The foreign matter cleaning refers to removing foreign matters from the crucible and wiping the crucible with medical alcohol. After the pre-assembly treatment of the crucible is completed, the crucible may be mounted.

In some embodiments, taking the open furnace shown in FIG. 2C as an example, the assembly process may include mounting a temperature field device. The operations of mounting the temperature field device may include but are not limited to the following content.

1: The bottom plate 222 may be mounted on a mounting aluminum plate of a crystal preparation furnace, and a levelness of the bottom plate 222 may be adjusted to meet the requirement of 0.02 mm/m.

2: The second cylinder 224 may be mounted on the bottom plate 222 and a concentricity and a verticality between the second cylinder 224 and the bottom plate 222 may be adjusted. The concentricity between the second cylinder 224 and the bottom plate 222 may be less than 0.5 mm, and the verticality between the second cylinder 224 and the bottom plate 222 may be less than 0.2 degrees.

3: The first cylinder 223 may be mounted on the bottom plate 222 and a concentricity and a verticality between the first cylinder 223 and the bottom plate 222 may be adjusted. The concentricity between the first cylinder 223 and the bottom plate 222 may be less than 0.5 mm, and the verticality between the first cylinder 223 and the bottom plate 222 may be less than 0.2 degrees. After mounting is completed, a connection between the first cylinder 223 and the bottom plate 222 may be sealed using a high temperature adhesive to ensure positive pressure and no air leakage.

4: A gap between the first cylinder 223 and the second cylinder 224 and a bottom of the second cylinder 224 may be with the filler 225, and a filling amount and a tightness may be determined according to a preparation condition for preparing the crystal.

5: The crucible 221 may be placed on the filler 225 filling in the bottom of the second cylinder 224, and a vertical spacing between an upper edge of the crucible 221 and an upper edge of the induction coil 2213 may be within a range of −20-6 mm. The vertical spacing may be changed according to the preparation condition for preparing the crystal.

6: The second heating device 228 may be mounted above the crucible 221.

7: The second cover plate 227 may be mounted on the second cylinder 224, and a concentricity between the second cover plate 227 and the first cylinder 223 and a concentricity between the second cover plate 227 and the second cylinder 224 may be adjusted, respectively.

8: A pressure ring and a sealing ring coated with vacuum grease may be mounted.

9: The first cover plate may be mounted on the first cylinder 223, and a concentricity between the first cover plate and the first cylinder 223 may be adjusted to ensure that the one or more first through holes on the first cover plate is coaxial with the corresponding one or more second through holes on the second cover plate 227. The pressure ring and the first cover plate may be connected by threads to press the sealing ring to achieve sealing, ensuring positive pressure and no air leakage.

10: An observation member may be mounted on the first cover plate, and a vent pipe/an outlet pipe may be connected to a gas passage. The entire temperature field device may be completely mounted.

In some embodiments, the first pretreatment may include high temperature calcination.

In some embodiments, the assembly process may include sealing the device 200 for preparing the scintillation crystal and then introducing the protective gas into the device 200. The sealing mode may include using the sealing ring, the vacuum grease, or other sealing materials at the connections between the various components of the device for preparing the scintillation crystal.

It is understandable that an appropriate protective gas can inhibit the volatilization of the reaction materials (e.g., SiO₂) to a certain extent, thereby reducing the problem of component deviation of the crystal during the preparation process. In some embodiments, the protective gas may be introduced into the sealed device 200 for preparing scintillation crystal (e.g., the temperature field device). The protective gas refers to a gas that enters from a certain inlet of the device 200 for preparing scintillation crystal and flows out from another outlet. In some embodiments, the protective gas may include an inert gas. It should be noted that the inert gas used in the present disclosure may include nitrogen (N₂), argon (Ar), etc. In order to ensure that the introduced protective gas does not affect the reaction materials (e.g., bringing in other impurities), the purity of the protective gas may be greater than 99.9%. In some embodiments, when the protective gas is introduced into the device for preparing the scintillation crystal, the flow rate of the protective gas may be within a range of 1-30 liters/min.

As shown in the following table, when the flow rate of the protective gas is within a range of 1-30 liters/min, the light output of the scintillation crystal is higher, i.e., the scintillation crystal has better scintillation performance:

| Flow rate (liters/min) | Light output of scintillation crystal |
|---|---|
| of protective gas | (channel address) |
| 0 | 70 |
| 1 | 135 |
| 8 | 130 |
| 15 | 125 |
| 26 | 120 |
| 30 | 85 |
| 35 | 80 |

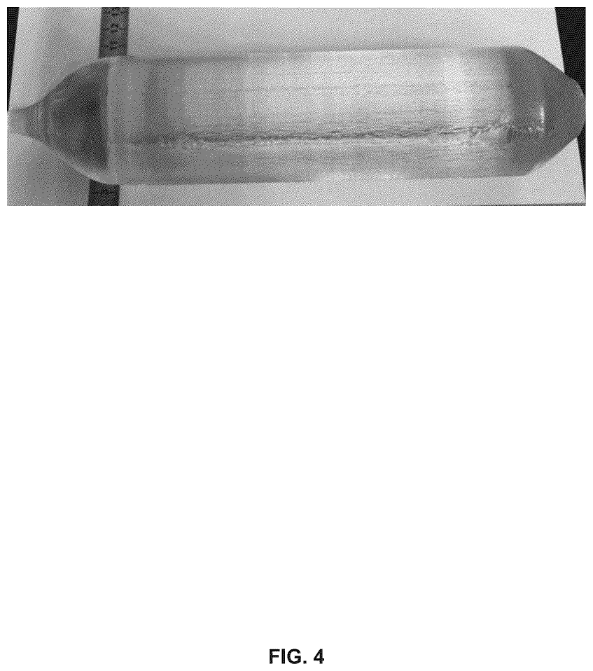

As shown in FIG. 4, after being fully oxidized (i.e., when the flow rate of the protective gas is 0), the scintillation crystal is yellow as a whole, and the light output is low.

In some embodiments of the present disclosure, by introducing the protective gas into the device for preparing the scintillation crystal, setting the protective gas to the inert gas, and setting the flow rate of the protective gas to be within a range of 1-30 liters/min, the degree of oxidation of the scintillation crystal during the preparation process of the crystal can be reduced, and the proportion of Ce³⁺ and/or Ce⁴⁺ in the scintillation crystal can be adjusted, such that the generated scintillation crystal is colorless and transparent (as shown in FIG. 1), and has a higher light output and better scintillation performance.

In some embodiments, after the assembly process of the device 200 for preparing the scintillation crystal is completed, the device 200 for preparing the scintillation crystal may be started to prepare the scintillation crystal using the up-pulling method. The device 200 for preparing the scintillation crystal may be started by powering on, and/or introducing a coolant (e.g., water). The reaction materials need to be heated and melted before the preparation of the crystal. After powering on, the induction coil in the device 200 for preparing the scintillation crystal may heat the crucible to melt the reaction materials included in the crucible. In some embodiments, during the preparation process of the crystal, the time for heating to melt the reaction material may be within a range of 5-48. It should be understood that the temperature required during the preparation process of the crystal is relatively high (e.g., 1900° C.), which may generate a large amount of heat radiation to the outside. However, if the preparation time of the crystal is too long (e.g., 4 days-40 days), long-term high temperature radiation may affect the performance of the device for preparing the scintillation crystal. Accordingly, the circulation coolant may be used to reduce heat radiation. The coolant may include water, ethanol, ethylene glycol, isopropanol, n-hexane, or the like, or any combination thereof. For example, the coolant may include a 50:50 mixture of water and ethanol.

In some embodiments, the scintillation crystal may be prepared by an up-pulling method (a Czochralski process) using the weighed reaction materials.

The up-pulling method may include processes such as material melting, preheating seed crystal, seeding, temperature adjustment, neck growth, crown growth, diameter equalizing, finishing, cooling, crystal extraction, etc.

The material melting refers to a process of heating to a specific temperature through a certain heating process, such that the reaction materials are completely melted to form a melt, and the device for preparing the scintillation crystal maintains an appropriate temperature (i.e., the temperature gradient). Since the crucible is used as a heating device in the device for preparing the scintillation crystal, the heat radiates from the crucible to the surrounding, forming a temperature gradient in the device. The temperature gradient refers to a change rate of the temperature of a certain point inside the device 200 for preparing the scintillation crystal to the temperature of another point nearby, and is also referred to as a change rate of the temperature within a unit distance. For example, if a temperature change between a point A and point B is T₁-T₂, and a distance between the point A and the point B is r₁-r₂, a temperature gradient from the point A to the point B may be ΔT=T₁-T₂/r₁-r₂. The scintillation crystal needs to have an appropriate temperature gradient during the preparation process. For example, during the preparation process of the scintillation crystal, only when the ΔT in the vertical direction is large enough can the crystallization latent heat generated during the preparation process of the scintillation crystal be transferred away in time to keep the preparation of the scintillation crystal stable. Meanwhile, the melt temperature below a preparation interface may be higher than the crystallization temperature, such that the scintillation crystal may not grow faster locally, the preparation interface may be stable, and the preparation may be stable. Maintaining the suitable temperature gradient may be determined by the position of a heating center. The heating center during material melting may affect the determination of the temperature gradient.

In some embodiments, during the process of heating and material melting, when a diameter of a polycrystalline material formed by the melting of the reaction materials and subsequent solidification melts to 50 mm, the heating may be stopped. After the heating is completed, the temperature may keep constant for 0.5-1 h or 0.2-1 h, and heating may be continued or cooling may be performed based on the melting of the reaction materials. An upper limit of heating may be determined based on a temperature or a heating power (e.g., the power of the induction coil) at which rod drawing is started when the scintillation crystal is prepared using the device 200 for preparing the scintillation crystal last time. For example, an output power of a medium frequency power supply may be appropriately adjusted to 50-300 w or the heating power may be adjusted to be 300-500 w less than the heating power when the last pulling is started. A heating rate may be determined based on a quotient between the temperature and the time (e.g., 24 h) when the last pulling is started. After the heating is completed, the temperature may keep constant for 0.5-1 h, and heating may be continued or cooling may be performed based on the melting of the reaction materials.

Preheating the seed crystal refers to fixing the seed crystal to a top of the lifting rod and slowly lowering the seed crystal to the temperature field during the heating and melting process, such that the temperature of seed crystal is close to the temperature of the melt, and the supercooled seed crystal is prevented from cracking after contacting the melt during subsequent operations. When the seed crystal is preheated, the seed crystal may keep at a distance from an upper surface of the reaction materials. Preferably, the seed crystal may keep at a distance of 5-100 mm from the upper surface of the reaction materials. In some embodiments, a diameter of the seed crystal used may be within a range of 4-12 mm. When the seed crystal is preheated, a lowering speed of the seed crystal may be within a range of 50-800 mm/h.

Seeding refers to lowering the lifting rod to bring the seed crystal into contact with the melt when the reaction materials are melted to a diameter less than a set value or completely melted to form a melt.

Temperature adjustment refers to adjusting a current temperature in the device for preparing the scintillation crystal to a temperature suitable for the preparation of scintillation crystal. During the temperature adjustment process, the seed crystal needs to be lowered again by 0.5-2 mm. In some embodiments, a temperature adjustment rate may be within a range of 100-300 w/0.1 h. After the temperature adjustment process is completed, the temperature inside the device for preparing the scintillation crystal may be maintained at 1950° C.-2100° C. for 0.2-2 h. After the temperature adjustment is completed, the screw rod may be rotated to drive the lifting rod to pull upward. After the seed crystal passes through the second cover plate and during the subsequent preparation process of the scintillation crystal, a rotation speed of the lifting rod may be within a range of 0.01-35 revolutions per minute.

Neck growth refers to a process of slowly increasing the temperature such that the zero point of the melt, i.e., the center point of a liquid surface in the crucible, is slightly higher than the melting point of the scintillation crystal, and the newly prepared scintillation crystal is rotated and pulled in the preparation process of the scintillation crystal until the diameter of the scintillation crystal slowly becomes smaller. Neck growth can reduce the dislocation of the scintillation crystal from the seed crystal to the single crystal below the neck.

Crown growth means when the atoms or molecules on the solid-liquid interface between the seed crystal and the melt begin to arrange according to the structure of the seed crystal, the temperature of the temperature field is slowly reduced according to a real-time preparation rate of the scintillation crystal, such that the seed crystal expands according to a preset angle. In some embodiments, a crown growth angle may be within a range of 30-70 degrees. A crown length may be within a range of 40-130 mm.

Diameter Equalizing means that the scintillation crystal grows into a rod structure of equal diameter according to a preset diameter reached during the crown growth process. In some embodiments, an equal diameter length of the prepared scintillation crystal may be within a range of 10-200 mm.

Finishing refers to lifting the scintillation crystal until the scintillation crystal is completely separated from the melt after the scintillation crystal grows to a preset length. The finishing may be a reverse operation of the crown growth. The diameter of the scintillation crystal may be reduced by changing a rising speed of the lifting rod until the scintillation crystal is separated from the melt, or the diameter of the scintillation crystal is reduced to a preset value. In some embodiments, a finishing angle may be within a range of 30-70 degrees. A finishing length may be within a range of 40-110 mm.

Cooling refers to a process of slowly cooling down after the finishing is completed to eliminate a stress formed in the scintillation crystal during high temperature preparation and prevent the scintillation crystal from cracking due to a sudden drop in temperature. In some embodiments, a cooling time of the scintillation crystal may be within a range of 20-100 h. In some embodiments, assuming that T is the temperature after the finishing is completed, a temperature drop rate of the scintillation crystal during the cooling process may be T/(20-100) h. In some embodiments, the temperature drop rate of the scintillation crystal may be within a range of 15-95° C./h. When an output heating power (e.g., the heating power of the induction coil) is 0, the preparation of the scintillation crystal may be ended.

Crystal extraction refers to opening the device to take out the prepared scintillation crystal when the temperature inside the device for preparing the scintillation crystal drops to the room temperature. During the entire preparation process of the scintillation crystal, a preparation rate of the scintillation crystal may be within a range of 0.01-6 mm/h based on the setting of various process parameters at different stages. Preferably, the preparation rate of the scintillation crystal may be within a range of 0.1-6 mm/h. The diameter of the obtained scintillation crystal may be within a range of 50-115 mm.

In some embodiments, the diameter of the prepared scintillation crystal may be ≥70 mm (e.g., 70-115 mm), and the equal diameter length of the prepared scintillation crystal may be 130 mm or more (e.g., 130-200 mm).

In some embodiments, a ratio of a weight of the prepared scintillation crystal to a weight of the melt formed by melting of the weighted reaction materials may be less than or equal to 70%.

In some embodiments of the present disclosure, by limiting the ratio of the weight of the prepared scintillation crystal to the weight of the melt formed by melting of the weighted reaction materials in the scintillation crystal, the effect of increasing the crystal yield can be achieved.

In some embodiments, the prepared scintillation crystal may include at least 5 ppm of a rare earth element cerium (3⁺). A mass ratio of Ca to Ce in the scintillation crystal may be less than 0.4.

In some embodiments, the prepared scintillation crystal has few macroscopic defects such as cracks and inclusions. According to the test, the crystal density can reach 7-7.4 g/cm³; the luminous central wavelength of the crystal can reach 350-340 nm; the light output can reach 35000 ph/MeV and above; the energy resolution can be ≤9%; and the minimum decay time can reach 35 nS and below. The excellent comprehensive performance of the crystal makes the crystal have important application potential in nuclear medicine, industrial CT, security inspection, environmental monitoring, and other fields.

In some embodiments, one or more operations in the preparation process of the scintillation crystal may be controlled by a PID (proportion, integral, and differential) controller, including but not limited to neck growth, crown growth, diameter equalizing, finishing, cooling, and other processes. In some embodiments, a PID parameter may be within a range of 0.1-5. Preferably, the PID parameter may be within a range of 0.5-4.5. More preferably, the PID parameter may be within a range of 1-4. More preferably, the PID parameter may be within a range of 1.5-3.5. More preferably, the PID parameter may be within a range of 2-3. Further preferably, the PID parameter may be within a range of 2.5-3.5.

In some embodiments, the method for preparing the scintillation crystal may further include: detecting the temperature gradient inside the crucible in real time using a temperature sensing device; in response to determining that a difference between a current temperature gradient and an initial temperature gradient is greater than a temperature gradient threshold, the control device automatically adjusting a structure and/or an operation parameter of the device for preparing the scintillation crystal, such that a temperature gradient of which a difference from the initial temperature gradient is less than the temperature gradient threshold is formed in the device for preparing the scintillation crystal. More descriptions regarding the temperature sensing device, the control device, and automatically adjusting the structure and/or the operation parameter of the device for preparing the scintillation crystal may be found in FIG. 2A.

The method for preparing the scintillation crystal is described in detail below through Examples 1-5. It should be noted that the reaction conditions, the reaction materials and the amounts of reaction materials in Examples 1-5 are only for illustrating the method for preparing the scintillation crystal and do not limit the protection scope of the present disclosure.

### Example 1

A scintillation crystal Lu_{2(1-x-y-s-z)}Ce₂ₓCa₂ₛSc_{2y}Y_{2z}SiO₅ was prepared using the device for preparing the scintillation crystal. A temperature field device was mounted according to the operations 1-5 of mounting the temperature field device in FIG. 3. Reaction materials with a purity of 99.9999% were calcined at 1000° C. (i.e., a calcination temperature) for 5 h and then naturally cooled to a room temperature of 35° C. and taken out. The reaction materials in the reaction equation were weighed in molar ratio. The reaction equation described above may be found in FIG. 3 and related descriptions thereof, wherein x=0.0016, y=0.02, s=0.0002, z=0.1, SiO₂ excess 0.3% of the weight, and other raw materials were weighed according to a stoichiometric ratio in the chemical equation. After weighing was completed, all the raw materials were placed in a three-dimensional mixer for mixing for 1 h (i.e., mixing time), and then taken out and placed in a press mold and pressed into a cylindrical block with a pressure of 200 MPa on a cold isostatic press. The materials were placed in an iridium crucible with a diameter of 150 mm and an inner height of 150 mm, the iridium crucible was placed in the mounted temperature field device, and a concentricity between the iridium crucible and the temperature field device was adjusted. A crucible position of the iridium crucible was set to +20 mm. The concentricity of the iridium crucible 214, the second heating device 228, the second cover plate 227, the first cover plate, and a weighing guide rod was adjusted in sequence, and the sealing between the first cover plate and the first cylinder 223 was ensured. After an observation member was assembled on the first cover plate, a protective gas N₂ was introduced into the temperature field device, and a circulation coolant was introduced. The parameters for preparing the crystal were set as the follows: the crystal diameter was set to 80 mm, the crown length was set to 95 mm, the equal diameter length was set to 180 mm, the finishing length was set to 30 mm, the heating time was set to 24 h, the rotation speed was set to 10 rpm, the pulling speed was set to 2 mm/h, the cooling time was set to 60 h, the PID value was set to 0.5, and the crystal density was 7.15 g/cm³. After the parameters were set, a Ce:Ca:L (Y/SC) SO seed crystal was located on the top of the lifting rod, and the concentricity between the seed crystal and the first cover plate was adjusted. The temperature was raised to start material melting, and the seed crystal was slowly lowered during the heating process for preheating. In order to avoid cracking of the seed crystal, the distance between the seed crystal and the material surface always kept at 5-15 mm. When material melting was finished, the seed crystal was slowly lowered to contact with the melt and the temperature as adjusted. During the temperature adjustment process, the seed crystal as lowered by 0.5-2 mm to fully melt the seed crystal and the melt, and the interface was complete, which reduces the cracking of the crystal caused by the seeding during the later cooling process of the crystal. After the temperature was appropriate, the automatic control program was started to enter an automatic preparation mode. After the process of neck growth, crown growth, diameter equalizing, finishing, and cooling, the preparation of the scintillation crystal was completed after 15 days (i.e. the preparation time).

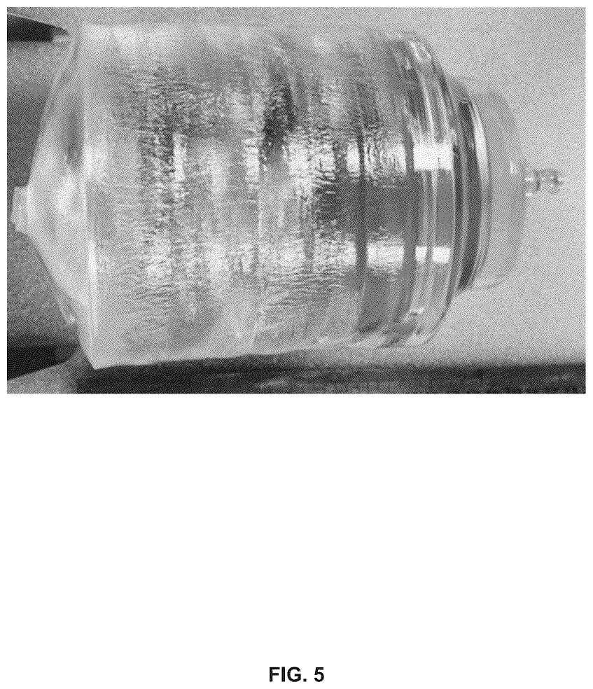

As shown in FIG. 5, the performance of the prepared scintillation crystal in this Example is as follows: the crystal is colorless, the appearance is normal and the same as the desired appearance, the crystal surface is rough and has a slight meltback strip. After the head and tail are removed and polished, the crystal is transparent inside. After irradiation with X-rays, no macroscopic defects such as point scattering, cloud layer, inclusions can be found in the scintillation crystal. After testing, the luminous central wavelength of the scintillation crystal is 420 nanometers; the light output of the scintillation crystal is 35200 ph/MeV; and the decay time of the scintillation crystal is ≤37 nanoseconds.

### Example 2

The specific operations and methods are found in Example 1. It should be noted that the following parameters are adjusted.

A prepared scintillation crystal is

$${Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} ,$$

wherein, x=0.0016, s=0.0008, z=0.15, n=1. The calcination temperature as 1200° C., the mixing time was 1-6 h, the diameter of the iridium crucible was 180 mm and the inner height of the iridium crucible was 180 mm. The protective gas used was argon (Ar), the crystal diameter as set to 105 mm, the crown length was set to 105 mm, the equal diameter length was set to 150 mm, the finishing length was set to 70 mm, the pulling speed was set to 1.5 mm/h, the cooling time was set to 100 h, the crystal density was 7.1 g/cm³, the seed crystal was LYSO, and the preparation time was 18 days.

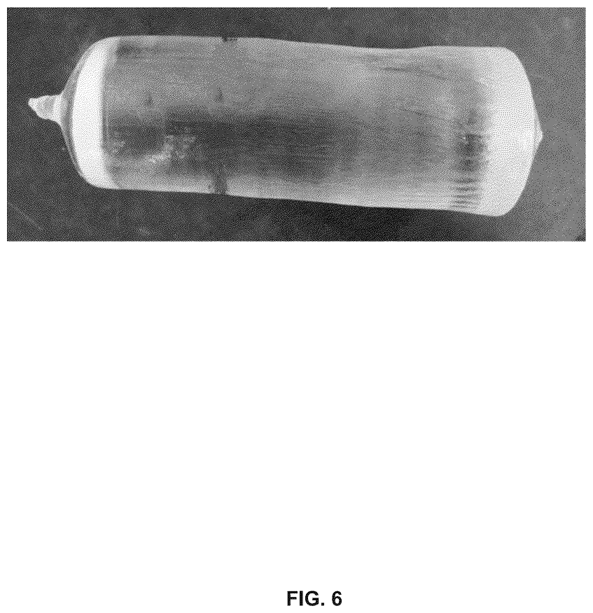

As shown in FIG. 6, the performance of the prepared scintillation crystal in this Example is as follows: the crystal is white, the appearance is normal and the same as the desired appearance, the crystal surface is rough and the meltback strip is obvious. After the head and tail are removed and polished, the crystal is transparent inside. After irradiation with X-rays, no macroscopic defects such as point scattering, cloud layer, inclusions can be found in the scintillation crystal. After testing, the luminous central wavelength of the scintillation crystal is 420 nanometers; the light output of the scintillation crystal is 35300 ph/MeV; the energy resolution of the scintillation crystal ≤9%; and the decay time of the scintillation crystal is ≤36 nanoseconds.

### Example 3

The specific operations and methods are found in Example 1. It should be noted that the following parameters are adjusted.

A prepared scintillation crystal is

$${Lu}_{2 ( 1 - x - s )} {Ce}_{2 x} {Ca}_{2 s} {SiO}_{( 5 - \frac{n}{2} )} {Cl}_{n} ,$$

wherein x=0.0016, s=0.0003, n=1. The calcination temperature was 1200° C., the mixing time was 1-6 h, the diameter of the iridium crucible was 180 mm and the inner height of the iridium crucible was 180 mm. The protective gas used was Ar, the crystal diameter as set to 90 mm, the crown length was set to 85 mm, the equal diameter length was set to 160 mm, the finishing length was set to 70 mm, the pulling speed as set to 1.5 mm/h, the cooling time was set to 100 h, the crystal density was 7.15 g/cm³, the seed crystal was LYSO, and the preparation time was 18 days.

As shown in FIG. 1, the performance of the prepared scintillation crystal in this Example is as follows: the crystal is white, the appearance is normal and the same as the set appearance, the crystal surface is rough and the meltback strip is obvious. After the head and tail are removed and polished, the crystal is transparent inside. After irradiation with X-rays, no macroscopic defects such as point scattering, cloud layer, inclusions can be found in the scintillation crystal. After testing, the luminous central wavelength of the scintillation crystal is 420 nanometers; the light output of the scintillation crystal is 35400 ph/MeV; the energy resolution of the scintillation crystal ≤9%; and the decay time of the scintillation crystal is ≤35 nanoseconds.

### Example 4

The specific operations and methods are found in Example 1. It should be noted that the following parameters are adjusted.

A prepared scintillation crystal is

$${Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} ,$$

wherein, x=0.0016, y=0.05, s=0.0003, z=0.1, n=1. The calcination temperature is 1200° C., the mixing time was 1-6 h, the diameter of the iridium crucible was 180 mm and the inner height of the iridium crucible was 180 mm. The protective gas used was N₂, the crystal diameter as set to 90 mm, the crown length was set to 85 mm, the equal diameter length was set to 160 mm, the finishing length was set to 70 mm, the pulling speed was set to 1.5 mm/h, the cooling time was set to 100 h, the crystal density was 7.1 g/cm³, the seed crystal was LYSO, and the preparation time was 18 days.

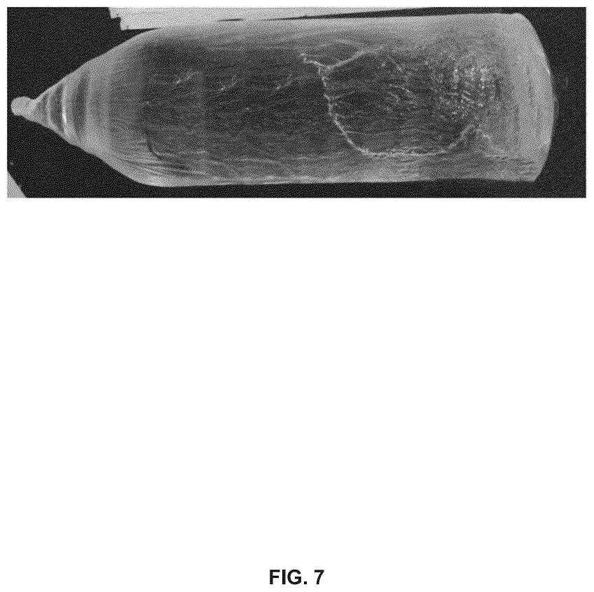

As shown in FIG. 7, the performance of the prepared scintillation crystal in this Example is as follows: the crystal is white, the appearance is normal and the same as the desired appearance, the crystal surface is rough and the meltback strip is obvious. After the head and tail are removed and polished, the crystal is transparent inside. After irradiation with X-rays, no macroscopic defects such as point scattering, cloud layer, inclusions can be found in the scintillation crystal. After testing, the luminous central wavelength of the scintillation crystal is 420 nanometers; the light output of the scintillation crystal is 35400 ph/MeV; the energy resolution of the scintillation crystal ≤9%; and the decay time of the scintillation crystal is ≤35 nanoseconds.

### Example 5

The specific operations and methods are found in Example 1. It should be noted that the following parameters are adjusted.

A prepared scintillation crystal is

$${Lu}_{2 ( 1 - x - s - z )} {Ce}_{2 x} {Ca}_{2 s} {Sc}_{2 y} {Y}_{2 z} {SiO}_{( 5 - \frac{n}{2} )} {Cl}_{n} ,$$

wherein, x =00016, s=0.0003, z=0.1, n=2. The calcination temperature was 1200° C., the mixing time was 1-6 h, the diameter of the iridium crucible was 180 mm and the inner height of the iridium crucible was 180 mm. The protective gas used was N₂, the flow rate was less than 15 liters/min, the crystal diameter as set to 90 mm, the crown length as set to 85 mm, the equal diameter length as set to 160 mm, the finishing length as set to 70 mm, the pulling speed as set to 1.5 mm/h, the cooling time as set to 100 h, the crystal density as 7.1 g/cm³, the seed crystal was LYSO, and the preparation time was 18 days.

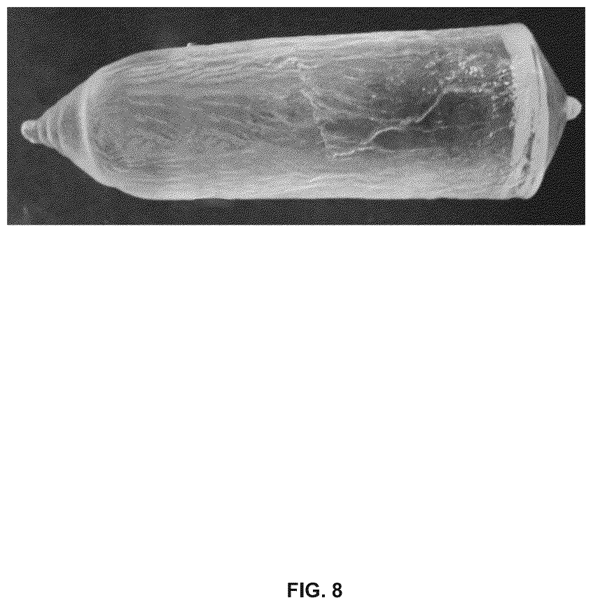

As shown in FIG. 8, the performance of the prepared scintillation crystal in this Example is as follows: the crystal is white, the appearance is normal and the same as the set appearance, the crystal surface is rough and the meltback strip is obvious. After the head and tail are removed and polished, the crystal is transparent inside. After irradiation with X-rays, no macroscopic defects such as point scattering, cloud layer, inclusions can be found in the scintillation crystal. After testing, the luminous central wavelength of the scintillation crystal is 420 nanometers; the light output of the scintillation crystal is 35300 ph/MeV; the energy resolution of the scintillation crystal ≤9%; and the decay time of the scintillation crystal is ≤35 nanoseconds.

The preparation repeatability and the performance repeatability of the scintillation crystal in the above Examples are both excellent because the uniformity of the overall temperature field is improved. By adjusting the size of each component in the temperature field, the relative position of the crucible in the temperature field, and the heating device above the crucible (if necessary), the temperature field or the temperature gradient of the temperature field required for the optimal preparation of the crystal can be obtained. By inhibiting volatilization of SiO₂ and compensation measures, optimizing the preparation process and parameters (e.g., matching the pulling speed, the rotation speed and the crystal diameter), optimizing the process condition, the preparation time of the crystal, and the weight of the crystal, and adjusting the Ce doping concentration and the compensation amount of SiO₂, the scintillation crystal with a large crystal diameter, good optical performance, and good preparation and performance repeatability is obtained.

The embodiments of the present disclosure are not limited to the above embodiments, and any other changes, modifications, substitutions, combinations, and simplifications made without departing from the spirit and principle of the present disclosure are deemed to be equivalent alternative methods and are included in the protection scope of the present disclosure.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure, or feature described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures, or features may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose and that the appended claims are not limited to the disclosed embodiments, but, on the contrary, are intended to cover modifications and equivalent arrangements that are within the spirit and scope of the disclosed embodiments.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

In some embodiments, numbers describing the number of ingredients and attributes are used. It should be understood that such numbers used for the description of the embodiments use the modifier “about”, “approximately”, or “substantially” in some examples. Unless otherwise stated, “about”, “approximately”, or “substantially” indicates that the number is allowed to vary by ±20%. Correspondingly, in some embodiments, the numerical parameters used in the description and claims are approximate values, and the approximate values may be changed according to the required features of individual embodiments. In some embodiments, the numerical parameters should consider the prescribed effective digits and adopt the method of general digit retention. Although the numerical ranges and parameters used to confirm the breadth of the range in some embodiments of the present disclosure are approximate values, in specific embodiments, settings of such numerical values are as accurate as possible within a feasible range.

For each patent, patent application, patent application publication, or other materials cited in the present disclosure, such as articles, books, specifications, publications, documents, or the like, the entire contents of which are hereby incorporated into the present disclosure as a reference. The application history documents that are inconsistent or conflict with the content of the present disclosure are excluded, and the documents that restrict the broadest scope of the claims of the present disclosure (currently or later attached to the present disclosure) are also excluded. It should be noted that if there is any inconsistency or conflict between the description, definition, and/or use of terms in the auxiliary materials of the present disclosure and the content of the present disclosure, the description, definition, and/or use of terms in the present disclosure is subject to the present disclosure.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

What is claimed is:

1. A scintillation crystal, wherein a molecular formula of the scintillation crystal is expressed as:
$${Lu}_{2 ( 1 - x - m - z )} {X}_{2 x} {M}_{2 m} {Y}_{2 z} {SiQ}_{( 5 - \frac{n}{2} )} {N}_{n} ,$$
wherein X is composed of Ce, M is composed of one or more of Ca, Mg, Sr, Mn, Ba, Al, Fe, Re, La, Pr, Nd, Pm, Sm, Eu, Gd, Tb, Dy, Ho, Er, Yb, Tm, Lu, and Sc, Q is composed of O, N is composed of Cl and one or more of F, Br, and S; wherein
$$x = 1. \times {10}^{- 7} - 0.06 , m = 0 - 0.06 , 0 \leq z < 1 , 0 < n < 10.$$

2. The scintillation crystal of claim 1, wherein X is composed of Ce, M is composed of Ca or M is composed of Ca and Sc, Q is composed of O, N is composed of Cl, and the molecular formula of the scintillation crystal is expressed as:
$${Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} ,$$
wherein,
0<s<0.05, 0≤y<1, and a ratio of a mass of Cl to a sum of masses of Lu, Ce, Sc, and Y is within a range of 0.01 ppm-1000 ppm.

3. The scintillation crystal of claim 2, wherein a mass ratio of Ca to Ce in the scintillation crystal is not greater than 300.

4. The scintillation crystal of claim 1, wherein a first dopant and a second dopant are added when the scintillation crystal is prepared, wherein
the first dopant is a compound including Ce, a mass ratio of Ce to a rare earth element in the first dopant being at least 10 ppm; and
the second dopant is a compound including M, a mass ratio of M to a rare earth element in the second dopant being within a range of 0.1 ppm-500 ppm.

5. A method for preparing the scintillation crystal of claim 1; wherein
a reaction equation for preparing the scintillation crystal is:
$$( 1 - x - y - s - z ) {Lu}_{2} {O}_{3} + {zY}_{2} {O}_{3} + {ySc}_{2} {O}_{3} + \frac{n}{3} {CeCl}_{3} + ( 2 x - \frac{n}{2} ) {CeO}_{2} + 2 sCaO + {SiO}_{2} = {Lu}_{2 ( 1 - x - y - s - z )} {Ce}_{2 x} {Ca}_{2 s} {Sc}_{2 y} {Y}_{2 z} {SiO}_{( 5 - \frac{n}{2} )} {Cl}_{n} + \frac{( x - s - \frac{n}{2} )}{2} {O}_{2} ,$$
wherein, x=0.0000001-0.06, 0<s<0.05, 0≤y<1, 0≤z<1, 0<n<10;
the method comprises:
weighing reaction materials according to a molar ratio based on the reaction equation; and
preparing the scintillation crystal using the weighed reaction materials.

6. The method of claim 5, wherein preparing the scintillation crystal using the weighed reaction materials includes:
before the reaction materials are weighed, performing a first pretreatment on the reaction materials;
weighing the reaction materials after the first pretreatment according to the molar ratio based on the reaction equation;
performing a second pretreatment on the weighed reaction materials; and
preparing the scintillation crystal using the weighted reaction materials after the second pretreatment.

7. The method of claim 6, wherein
the first pretreatment includes high temperature calcination at 100° C.-1400° C.; and
the second pretreatment includes mixing the weighed reaction materials at room temperature; or
heating the weighed reaction materials to a preset temperature and mixing the heated reaction materials.

8. The method of claim 5, wherein preparing the scintillation crystal using the weighed reaction materials includes:
introducing a protective gas into a device for preparing the scintillation crystal, wherein the protective gas is an inert gas, and a flow rate of the protective gas is within a range of 1-30 liters/min.

9. The method of claim 5, wherein a ratio of a weight of the prepared scintillation crystal to a weight of a melt formed by melting of the weighted reaction materials is less than or equal to 70%.

10. A device for preparing the scintillation crystal of claim 1, comprising a furnace chamber, a temperature field device, a lifting rod, a first heating device, a first driving device, and a crucible; wherein
the temperature field device and the first heating device are disposed in the furnace chamber;
the crucible is disposed in the temperature field device and configured to accommodate reaction materials for preparing the scintillation crystal;
at least a portion of the lifting rod is disposed in the furnace chamber; and
the first driving device is connected with the lifting rod to drive the lifting rod to move along an axial direction of the lifting rod.

11. The device of claim 10, wherein a thickness of the crucible is within a range of 0.8 mm-3 mm.

12. The device of claim 10, wherein the temperature field device includes a filler, and at least a portion of the crucible is disposed in the filler.

13. The device of claim 12, wherein the whole crucible is disposed in the filler.

14. The device of claim 12, wherein the filler includes zircon sand or zirconium fibers.

15. The device of claim 10, wherein heat generated during preparation of the scintillation crystal forms one or more convection loops between at least two of the furnace chamber, the temperature field device, or the first heating device.

16. The device of claim 10, wherein for a first portion of a crucible wall of the crucible,
a thickness of the first portion is greater than a thickness of at least a portion of the rest portion of the crucible wall of the crucible; and/or
the first portion is provided with a reinforcing rib; wherein
the first portion is located at a first preset distance below an opening of the crucible.

17. The device of claim 10, wherein for a second portion of a crucible wall of the crucible,
a thickness of the second portion of the crucible wall is greater than a thickness of at least a portion of the rest portion of the crucible wall of the crucible; and/or
the second portion is provided with a reinforcing rib; wherein
the second portion is located at a second preset distance above a bottom of the crucible.

18. The device of claim 10, wherein a bottom of the crucible is a flat bottom, a thickness of a target region on the flat bottom is greater than a thickness of the rest region of the flat bottom, and the target region is a region within a preset range from a center of the flat bottom.

19. The device of claim 10, further comprising:
a temperature sensing device, disposed on an outer wall of the crucible and configured to obtain a temperature gradient in the crucible in real time; and
a control device, configured to automatically adjust a structure and/or an operation parameter of the device for preparing the scintillation crystal in response to detecting that a difference between a current temperature gradient and an initial temperature gradient is greater than a temperature gradient threshold, such that the device for preparing the scintillation crystal forms a target temperature gradient in the crucible, a difference between the target temperature gradient and the initial temperature gradient is less than the temperature gradient threshold.

20. The device of claim 19, wherein automatically adjusting the structure and/or the operation parameter of the device for preparing the scintillation crystal includes at least one of:
adjusting a position of the first heating device;
adjusting a heating power of the first heating device;
adjusting a position of the crucible;
adjusting a position of a second heating device, the second heating device being disposed in the temperature field device and above the crucible; or
adjusting a heating power of the second heating device.
